(19) United States
(12) Patent Application Publication
(10) Pub. No.: US 2006/0086958 A1
(43) Pub. Date: Apr. 27, 2006

(54) Wire structure, semiconductor device, MRAM, and manufacturing method of semiconductor device

(75) Inventor: Takahisa Eimori, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/248,306

(22) Filed: Oct. 13, 2005

(30) Foreign Application Priority Data
Oct. 22, 2004 (JP) 2004-308390
Aug. 29, 2005 (JP) 2005-247860

(51) Int. Cl. H01L 29/94

(52) U.S. Cl. 257/301

(57) ABSTRACT

The present invention provides a wire structure where reduction in the amount of current that can be made to flow through the wire can be suppressed (a current comprising a large current density can be made to flow), even in the case where the wire is downsized. A wire structure according to the present invention is provided in an insulating film formed on a base. Here, a trench is formed in the surface of the insulating film. In addition, a plurality of carbon nanotubes are included in this trench. That is, the wire structure according to the present invention includes at least a plurality of carbon nanotubes.

### BACKGROUND OF THE INVENTION

1. Field of the Invention

The present invention relates to a wire structure, a semiconductor device, an MRAM, and a manufacturing method of a semiconductor device. In particular, the present invention relates to a wire structure that includes carbon nanotubes, a semiconductor device, an MRAM, and a manufacturing method of a semiconductor device.

2. Description of the Background Art

Conventional semiconductor devices having a copper wire structure formed in accordance with a Damascene method have existed conventionally (see “Research Report of Trends in Technologies Filed as Patent Applications in Fiscal Year 2003, Multilayer Wire Technologies of LSI (Abridged Version), March 2004, p. 3, FIGS. 1 and 2,” by Japan Patent Office).

Here, in the case where a current of which the current density is about 10⁷ A/cm² flows through a copper wire, this copper wire is fused and cut. In addition, in the case where a current of which the current density is about 10⁵ A/cm² flows through a copper wire, a migration phenomenon occurs in this copper wire.

Together with recent downsizing of semiconductor devices, copper wire structures have also required to be downsized. Thus, the value of the current that is allowed to flow through these downsized copper wires cannot help being made smaller, taking into consideration the migration phenomenon and the like that occurs in copper wires.

### SUMMARY OF THE INVENTION

An object of the present invention is to provide a wire structure where reduction in the amount of current that can be made to flow through the wire can be suppressed, even in the case where the wire is downsized, as well as a semiconductor device, an MRAM and a manufacturing method of a semiconductor device.

According to a first aspect of the present invention, there is provided a wire structure for a semiconductor device, where the semiconductor device includes an insulating film that is formed on a base. The wire structure includes a trench and carbon nanotubes. The trench is formed in the surface of the insulating film. The carbon nanotubes exist within the trench. In addition, the plurality of carbon nanotubes is great.

A current having a large current density can be made to flow through this wire. Accordingly, even in the case where the wire is downsized, it is not necessary to reduce the amount of current that flows through it.

According to a second aspect of the present invention, there is provided a semiconductor device comprising the wire structure according to claim 1.

It is possible to provide a semiconductor device having a wire where a current driving force has increased.

According to a third aspect of the present invention, there is provided an MRAM including a first wire, a second wire and an MTJ film. The first wire is provided above a semiconductor substrate. The second wire exists above the semiconductor substrate and below the first wire, and crosses the first wire in a plan view. The MTJ film exists between the first wire and the second wire. In addition, at least one of the first wire and the second wire comprises a wire structure according to claim 11. In addition, no catalyst film is formed on a surface that faces the MTJ film in this wire structure.

Shield effects are attained in the first wire or the second wire, and an increase in the current driving force of such a wire can be achieved.

According to a fourth aspect of the present invention, there is provided a manufacturing method of a semiconductor device, including the steps (a) to (d). In the step (a), an insulating film is formed on a base. In the step (b), a trench for a wire is formed in the surface of the insulating film. In the step (c), a catalyst film is formed inside the trench. In the step (d), carbon nanotubes are grown on the catalyst film.

The carbon nanotubes can be grown in a direction comprising a direction component direction in which the trench extends. Accordingly, the resistance of the entire wire can be reduced. Here, an electrical field comprising a direction component in which the trench extends, for example, is applied, so that the carbon nanotubes can be grown in a desired direction on the catalyst film.

According to a fifth aspect of the present invention, there is provided a manufacturing method of a semiconductor device, including the steps (A) to (D). In the step (A), an insulating film is formed on a base. In the step (B), a trench for a wire is formed inside the surface of the insulating film. In the step (C), a plurality of catalyst films in island form are formed on at least one inner surface of the trench in the direction in which the trench extends. In the step (D), carbon nanotubes are grown in a state where the catalyst films in island form are attached to tip ends of the carbon nanotubes which do not make contact with an inner surface of the trench.

It becomes unnecessary to attach a catalyst film to the sides or the like of the trench in a completed wire. Accordingly, the occurrence of a junction leak in the insulating film, which may be caused by a catalyst film being attached to the inside of the trench, can be prevented.

According to a sixth aspect of the present invention, there is provided a semiconductor device including the wire structure according to claim 22.

It is possible to provide a semiconductor device comprising a wire of which the current driving force is increased.

According to a seventh aspect of the present invention, there is provided a manufacturing method of a semiconductor device, including the steps (a) to (d). In the step (a), an insulating film is formed on a base. In the step (b), a trench for a wire is formed in the surface of the insulating film. In the step (c), a plurality of partitioning conductive films, which are formed of catalyst films and partition the trench along the direction in which the trench extends, are formed. In the step (d), carbon nanotubes are grown so as to connect the partitioning conductive films.

The carbon nanotubes can be grown in a direction comprising a direction component in which the trench extends. Accordingly, the resistance of the entire wire can be reduced. Furthermore, effects such as an increase in the current density of a current that flows through the wire, suppression of fusion cutting of the wire, and restriction of the occurrence of migration can be attained.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an enlarged perspective view showing the configuration of a wire structure according to a first embodiment;

FIG. 2 is an enlarged top view showing the configuration of the wire structure according to the first embodiment;

FIG. 3 is a perspective cross-sectional view showing the configuration of the wire structure according to the first embodiment;

FIGS. 4 to 7 are cross-sectional views showing steps for illustrating a manufacturing method of the wire structure according to the first embodiment;

FIG. 8 is a perspective cross-sectional view showing the configuration of a wire structure according to a second embodiment;

FIGS. 9 to 12 are cross-sectional views showing steps for illustrating a manufacturing method of the wire structure according to the second embodiment;

FIG. 13 is a cross-sectional view showing a structure where no barrier film is provided to the wire structure according to the second embodiment;

FIG. 14 is a perspective cross-sectional view showing the configuration of a wire structure according to a third embodiment;

FIGS. 15 to 17 are cross-sectional views showing steps for illustrating a manufacturing method of the wire structure according to the third embodiment;

FIG. 18 is a perspective cross-sectional view showing a wire structure where a trench in the wire structure according to the third embodiment is filled in with a conductor;

FIG. 19 is a perspective cross-sectional view showing the configuration of a wire structure according to a fourth embodiment;

FIGS. 20 and 21 are cross-sectional views showing steps for illustrating a manufacturing method of the wire structure according to the fourth embodiment;

FIGS. 22 and 23 illustrate the effects of the wire structure according to the fourth embodiment;

FIG. 24 is a perspective cross-sectional view showing the configuration of a wire structure according to a fifth embodiment;

FIG. 25 is a perspective view showing the configuration of the wire structure according to the fifth embodiment;

FIGS. 26 to 28 are cross-sectional views showing steps for illustrating a manufacturing method of the wire structure according to the fifth embodiment;

FIG. 29 is a perspective cross-sectional view showing a structure where a trench in the wire structure according to the fifth embodiment is filled in with a conductor;

FIG. 30 is a perspective view showing the configuration of an MRAM;

FIG. 31 shows the state of a magnetic field (magnetic flux) that is generated when a current flows through a wire structure according to a sixth embodiment;

FIG. 32 shows the positional relationship between a wire and an MTJ film according to the sixth embodiment;

FIGS. 33 to 37 are cross-sectional views showing steps for illustrating a manufacturing method of the wire structure according to the sixth embodiment;

FIG. 38 is a perspective cross-sectional view showing the configuration of the wire structure according to the sixth embodiment, where a trench is filled in with a conductor;

FIG. 39 is a perspective cross-sectional view showing the configuration of the wire structure according to the sixth embodiment, where the growth of carbon nanotubes has been stopped partway through;

FIGS. 40 to 43 are cross-sectional views showing steps for illustrating a manufacturing method of a wire structure according to a seventh embodiment;

FIGS. 44 and 45 are cross-sectional views showing steps for illustrating a manufacturing method of a wire structure according to an eighth embodiment;

FIGS. 46 and 47 are top views for illustrating a manufacturing method of a wire structure according to a ninth embodiment;

FIG. 48 is a perspective cross-sectional view showing the configuration of another example of a wire structure according to the present invention;

FIG. 49 is a perspective view showing a wire structure according to a tenth embodiment;

FIG. 50 is a perspective view showing a wire structure according to an eleventh embodiment;

FIG. 51 is a perspective view showing a wire structure according to a twelfth embodiment;

FIG. 52 is a schematic plan view showing the wire structure according to the twelfth embodiment;

FIG. 53 is a cross-sectional view showing a via made of carbon nanotubes for connecting wires to each other;

FIG. 54 is a perspective view showing the configuration of another example of the wire structure according to the twelfth embodiment;

FIGS. 55 to 59 are cross-sectional views showing steps for illustrating a manufacturing method of a wire structure according to a thirteenth embodiment; and

FIGS. 60 to 63 are cross-sectional views showing steps for illustrating a manufacturing method of a wire structure according to a fourteenth embodiment.

### DESCRIPTION OF THE PREFERRED EMBODIMENTS

The present invention has a feature in that cylindrical structures formed of carbon elements are included in at least a part of a wire. These structures are typically carbon nanotubes. Here, a wire structure according to the present invention can be provided within an interlayer insulating film of a semiconductor device.

Carbon nanotubes form a new carbon-based material that has recently received attention because of its unique characteristics. Carbon nanotubes have a structure where a graphite sheet where carbon atoms are assembled into six-membered ring form with sp2 bonds, which are the strongest type of bond, is rolled into a cylindrical form. In addition, a tip end of a tube is closed with several six-membered rings, including five-membered rings.

The diameter of a tube can be miniaturized to the order of sub-nanometers, and the minimum is about 0.4 nm.

In addition, carbon nanotubes have a thermal conductivity which exceeds that of diamond, and a permissible current density of 10⁹ A/cm² or more. In addition, these carbon nanotubes are known to have a high Young's modulus.

Carbon nanotubes can be formed by means of arc discharge, laser ablation or the like. In recent years, it has become possible to form nanotubes by means of a plasma CVD method, a thermal CVD method or the like.

In the following, the present invention (wire structures that include carbon nanotubes, and the like) is concretely described with reference to the drawings which show embodiments thereof.

### First Embodiment

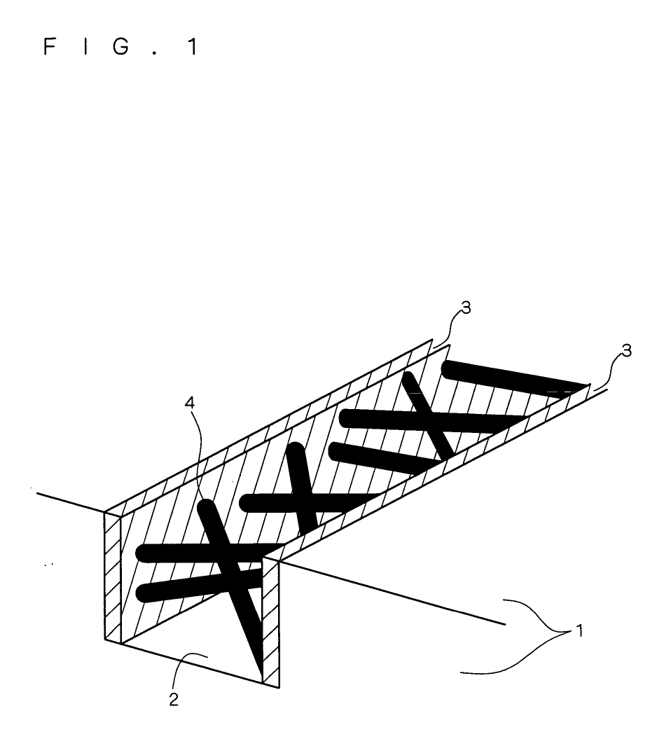

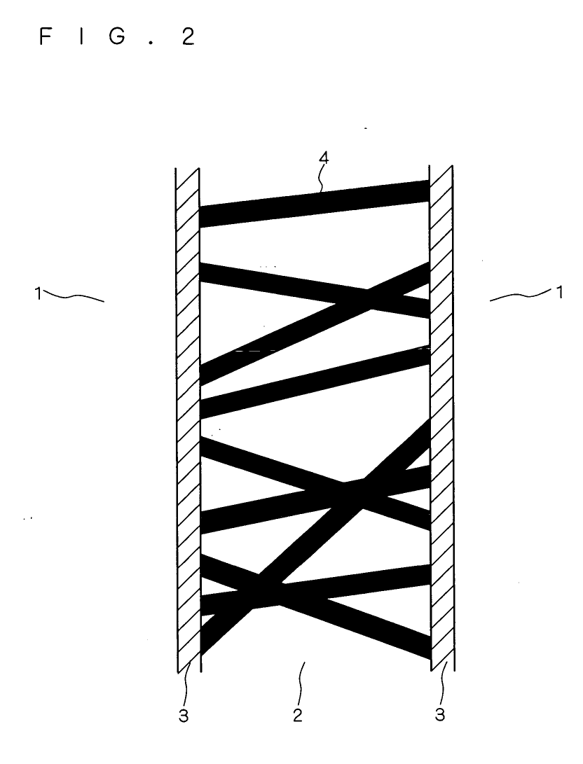

FIG. 1 is an enlarged perspective view showing a wire structure according to a first embodiment. In addition, FIG. 2 is a top view showing the wire structure according to this embodiment. In addition, FIG. 3 is a perspective cross-sectional view showing the wire structure according to this embodiment.

Here, FIGS. 1, 2 and 3 depict only several carbon nanotubes 4, for the purpose of simplifying the drawings. Actually, however, the carbon nanotubes 4 exist in a trench 2 more densely than in the figures. In addition, the directions in which the carbon nanotubes 4 grow are more complex actually, and carbon nanotubes grow in random directions.

As shown in FIGS. 1 to 3, an interlayer insulating film 1 is formed on a semiconductor substrate 10. A trench 2 of which the cross section is approximately rectangular is formed in the surface of the interlayer insulating film 1. In addition, conductive catalyst films 3 are formed on the surface on both sides of the trench 2.

Here, the catalyst films 3 are formed on the entirety of the surfaces, in the direction in which this trench 2 extends. In addition, the catalyst films 3 for the carbon nanotubes 4 can be made of a transition metal or a compound having a transition metal. Zinc, cobalt, nickel, iron, rhodium, palladium and the like, for example, can be applied.

In addition, as shown in FIGS. 1 to 3, a great number of carbon nanotubes 4 are formed so as to reach from one catalyst film 3 to the other catalyst film 3. Here, the carbon nanotubes 4 are formed at angles which are not perpendicular to the direction in which the trench 2 extends (the carbon nanotubes 4 are formed at predetermined angles relative to the direction of the normal of the sides of the trench 2).

Next, a manufacturing method of the wire structure according to this embodiment is concretely described with reference to the cross-sectional views showing the steps thereof.

First, as shown in FIG. 4, an interlayer insulating film 1 is formed on a semiconductor substrate 10 in accordance with, for example, a CVD (Chemical Vapor Deposition) method.

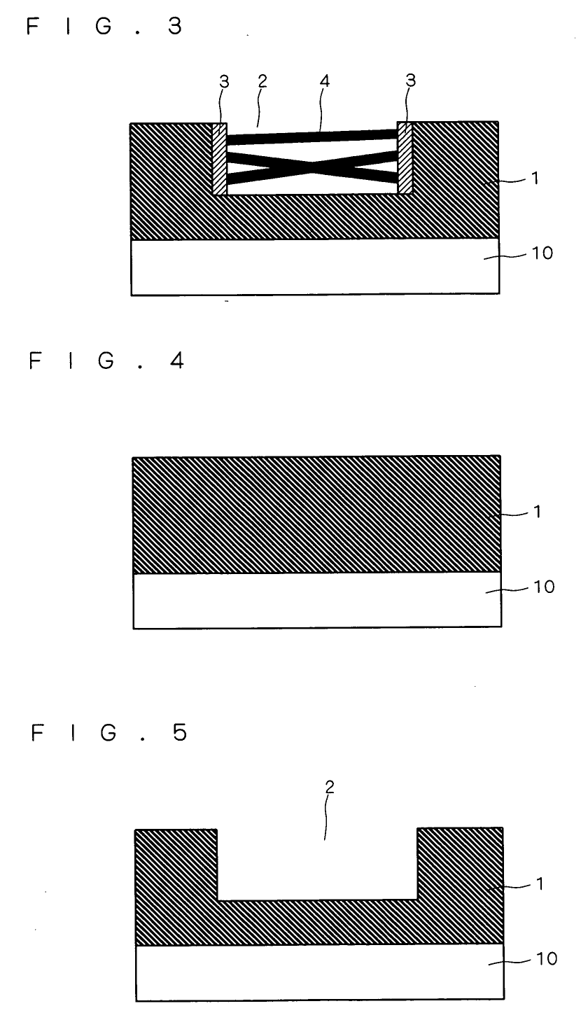

Next, a photolithographic process is carried out, so that a trench 2 of which the cross section is in rectangular form is formed in the surface of the interlayer insulating film 1 as shown in FIG. 5.

Next, as shown in FIG. 6, a catalyst film 3 having a predetermined film thickness is formed on the interlayer insulating film 1 and inside the trench 2 in accordance with, for example, a CVD method. Here, as shown in FIG. 6, the catalyst film 3 is formed on the two sides and the bottom of the trench 2.

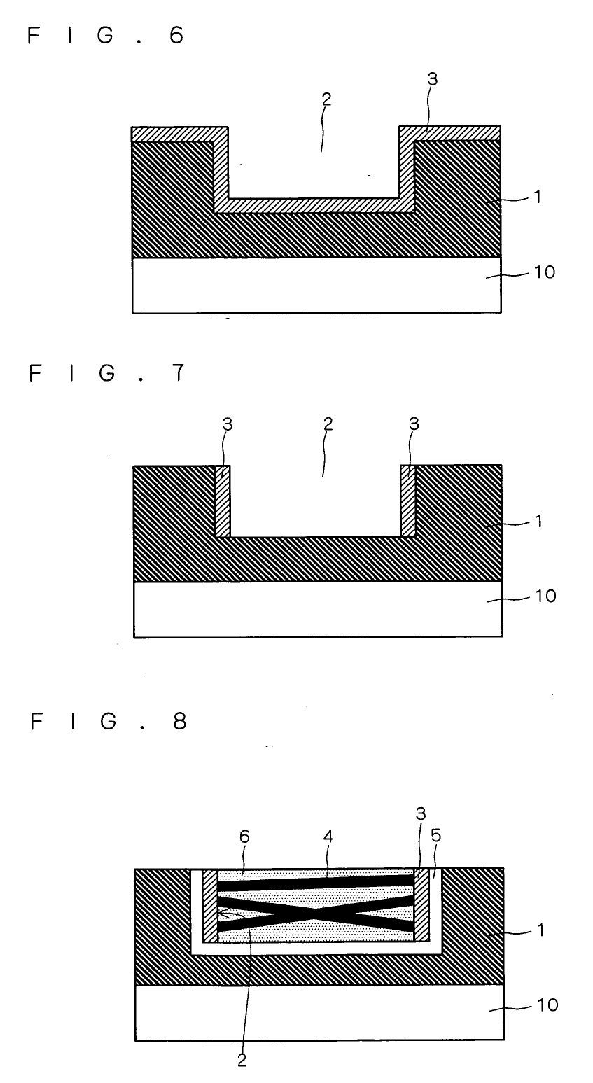

Next, anisotropic etching is carried out on the catalyst film 3. As a result of this, the catalyst film 3 remains only on the two sides of the trench 2 as shown in FIG. 7.

After that, a process is carried out in accordance with a thermal CVD method or the like, so that the carbon nanotubes 4 grow on the catalyst film 3. Here, the carbon nanotubes 4 grow so as to reach from one side (one catalyst film 3) to the other side (the other catalyst film 3) of the trench 2.

Here, a process for growing the carbon nanotubes 4 is carried out simply in accordance with a thermal CVD method, without applying an electrical field. In this case, the carbon nanotubes 4 grow in random directions.

As a result of the aforementioned steps, the wire structure shown in FIGS. 1 to 3 is completed.

As described above, the wire structure according to this embodiment is formed by growing a great number of carbon nanotubes in the trench 2. Accordingly, the wire structure according to this embodiment has the following effects.

The carbon nanotubes 4 are not made of a metal; therefore, no migration phenomenon occurs. Accordingly, no defects, such as an increase in the resistance or disconnection, which are caused by a migration phenomenon and become problems in the case of copper wires, occur in the wires.

In addition, the carbon nanotubes 4 allow a current of which at least the current density is 10⁹ A/cm² or more to flow. Accordingly, at least in the case where a current of which the current density is about 10⁹ A/cm² flows through the carbon nanotubes 4, these carbon nanotubes 4 do not disconnect.

Accordingly, by adopting this wire structure that includes the carbon nanotubes 4, a current of which the amount is greater than that in the case of a copper wire can be allowed to flow through the wire structure. Therefore, the wire structure according to this embodiment can be adopted, and a sufficient amount of current for the operation of a semiconductor device can be allowed to flow through this wire structure, even in the case where the wire structure is miniaturized (downsized) with the progress of recent trends. That is, even in the case where a wire is downsized, it is not necessary to reduce the amount of current that flows through it.

Here, the more densely the carbon nanotubes 4 are grown in the trench 2, the more the average amount of current that flow through a wire can be increased.

In this embodiment, the catalyst film 3 is conductive. This is because the catalyst film 3 is also utilized as a means for conveying a current.

However, the carbon nanotubes 4 are usually formed so densely as to make contact with each other. Thus, a current can be made to flow between the carbon nanotubes 4 via these portions that make contact.

Accordingly, in the case of such a configuration (that is, a case other than the case where the carbon nanotubes 4 are intentionally formed sparsely), it is not always necessary for the catalyst film 3 to have conductivity, which is the same in the following embodiments.

Here, in the case where the catalyst film 3 is formed continuously along one inner surface of the trench 2, as in the wire structure according to this embodiment, the carbon nanotubes 4 are formed so densely as to make contact with each other.

The carbon nanotubes 4 grow on the catalyst film 3 by creating their own tissue, and it is very difficult to grow these carbon nanotubes 4 to a length of several μm or longer. That is, there is a limit to the length of the grown carbon nanotubes 4.

Accordingly, the catalyst films 3 are formed on the two sides of the trench 2, as in the wire structure according to this embodiment, so that the length to which the carbon nanotubes 4 grow is limited only by the width of the wire (width in the lateral direction in FIG. 3). That is, the wire structure according to this embodiment can be formed by growing carbon nanotubes 4 having a short length; thus, the manufacturing thereof can be facilitated.

### Second Embodiment

FIG. 8 is a perspective cross-sectional view showing a wire structure according to a second embodiment.

As shown in FIG. 8, in the wire structure according to this embodiment, the inside of a trench 2 in which carbon nanotubes 4 are formed is filled in with a conductor (for example, copper) 6. Furthermore, a barrier film 5 is formed in order to prevent the diffusion of this conductor 6 into an interlayer insulating film 1.

This barrier film 5 is formed on the inner surfaces of the sides and the bottom of the trench 2. Here, the barrier film 5 is formed between the interlayer insulating film 1 and the conductor 6 on the bottom and between catalyst films 3 and the interlayer insulating film 1 on the sides of the trench 2. This is because the carbon nanotubes 4 are not prevented from growing on the catalyst films 3.

The other configurations are the same as those of the wire structure according to the first embodiment.

Next, a manufacturing method of the wire structure according to this embodiment is concretely described with reference to the cross-sectional views showing the steps thereof.

First, a structure as shown in FIG. 5 is prepared.

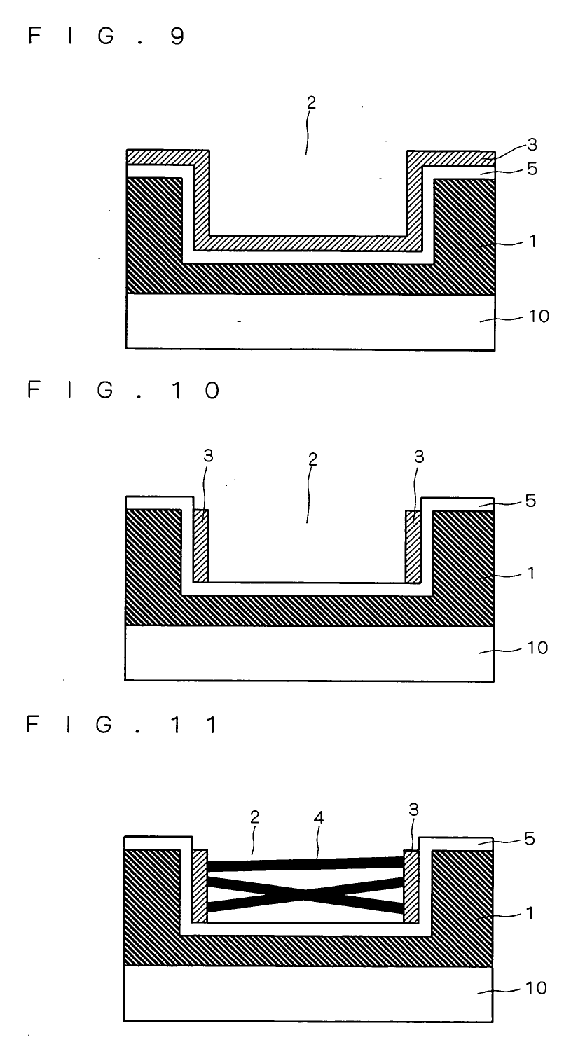

Next, a barrier film 5, having a predetermined film thickness, is formed on the interlayer insulating film 1 and inside the trench 2 as shown in FIG. 9 in accordance with, for example, a sputtering method. As shown in FIG. 9, the barrier film 5 is formed on the two sides and on the bottom of the trench 2.

Next, a catalyst film 3, having a predetermined film thickness, is formed on the barrier film 5, as shown in FIG. 9, in accordance with, for example, a CVD method.

Next, anisotropic etching is carried out on the catalyst film 3. As a result of this, as shown in FIG. 10, the catalyst film 3 remains only on the two sides of the trench 2 via the barrier film 5. Here, the barrier film 5 functions as an etching stopper.

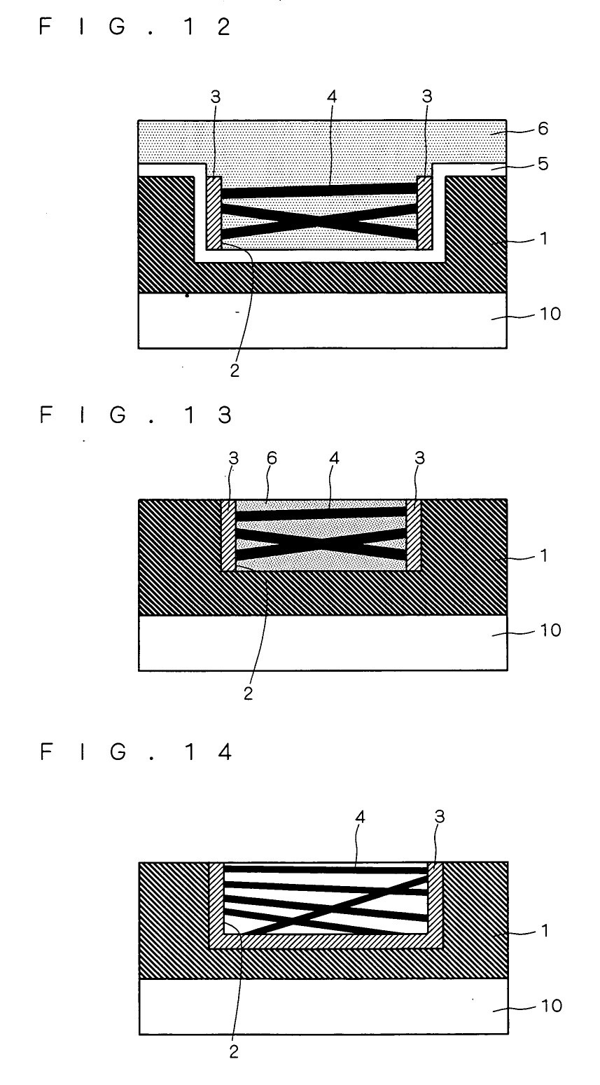

Next, carbon nanotubes 4 are grown on the catalyst films 3 as shown in FIG. 11 in accordance with a thermal CVD method. Here, the carbon nanotubes 4 are grown so as to reach from one side to the other side of the trench 2 in the same manner as in the first embodiment.

Next, a conductor (for example, copper) 6 is formed so as to fill in the trench 2 in which the carbon nanotubes 4 are formed as shown in FIG. 12 in accordance with, for example, a plating method.

After that, the portions of the conductor 6 and the barrier film 5 which exist on the interlayer insulating film 1 are removed by carrying out a CMP (Chemical and Mechanical Polishing) process.

As a result of the aforementioned steps, a wire structure as shown in FIG. 8 is completed.

In the wire structure according to this embodiment, the inside of the trench 2 where the carbon nanotubes 4 have grown is filled in with the conductor 6 as described above.

Accordingly, it becomes possible in the wire structure according to this embodiment to allow a greater amount of current to flow in the wire structure having the same size than in the wire structure according to the first embodiment. This is because the conductor 6 also conveys the current.

Here, the aforementioned effects become greater by adopting copper, having lower resistance than other materials, as the conductor 6.

In addition, even in the case where cracking occurs in the conductor 6 as a result of a migration phenomenon, there are no influences on the carbon nanotubes 4 from this migration phenomenon. In addition, even in the case where cracking occurs on the conductor 6, the carbon nanotubes 4 do not disconnect. Accordingly, even in the case where cracking occurs, for example, in the conductor 6, the wire functions normally.

Here, the catalyst films 3 serve, to a certain extent, to suppress the diffusion of the conductor 6 into the interlayer insulating film 1. Accordingly, it is also possible to omit the barrier film 5 in the case where the catalyst films 3 are formed inside the trench 2.

However, the barrier film 5 is additionally provided as in this embodiment, so that the diffusion of the conductor 6 into the interlayer insulating film 1 can surely be prevented.

As described above, the barrier film 5 is provided for the purpose of preventing the diffusion of the conductor 6 into the interlayer insulating film 1. This diffusion becomes a problem in the case where copper, for example, is adopted as the conductor 6. Accordingly, in the case where a conductor 6 (for example, aluminum or the like), in which the aforementioned diffusion does not become a problem, is adopted, the barrier film 5 can be omitted.

In the following embodiments, a myriad of variations of the wire configuration where the trench 2 is not filled in with a conductor 6 are described. It is of course possible to fill in the trench with a conductor 6 in these variations of the wire structure.

Here, in the case where this conductor 6 does not cause a problem of the aforementioned diffusion, it is not necessary to form a barrier film 5 as described above. In addition, in the case where the aforementioned diffusion of the conductor 6 becomes a problem, only the formation of catalyst films 3 can suppress to a certain extent the diffusion of the conductor 6 into the interlayer insulating film 1. However, the aforementioned diffusion can surely be prevented by providing the barrier film 5 as described above.

It is assumed that the diffusion of the conductor 6 into the interlayer insulating film 1 does not become a problem when the trench 2 is filled in with the conductor 6, for example, in the wire structure (FIGS. 1 to 3) according to the first embodiment. Then, it is sufficient to fill in the trench in the wire structures shown in FIGS. 1 to 3 with the conductor 6 (FIG. 13), and it is not necessary to provide an additional barrier film 5 as in the wire structure shown in FIG. 8.

Here, in this embodiment, the carbon nanotubes 4 and the conductor 6 become a carrier of electrons (that is, means for conveying a current); therefore, the catalyst films 3 may not have conductivity.

### Third Embodiment

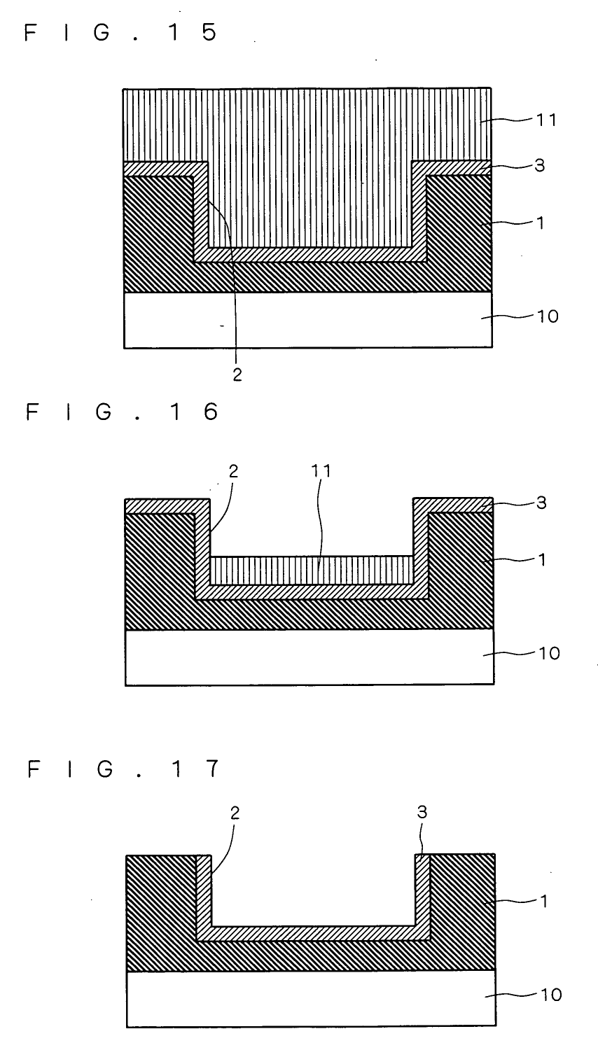

FIG. 14 is a perspective cross-sectional view showing a wire structure according to a third embodiment.

As shown in FIG. 14, a catalyst film 3 having conductivity is also formed on the bottom of the trench 2 in the wire structure according to this embodiment. Accordingly, as shown in FIG. 14, carbon nanotubes 4 also grow on the catalyst film 3 that exists on the bottom of the trench 2.

The other configurations are the same as those in the wire structure according to the first embodiment.

Next, a manufacturing method of the wire structure according to this embodiment is concretely described with reference to the cross-sectional views showing the steps thereof.

First, a structure as shown in FIG. 6 is prepared.

Next, as shown in FIG. 15, a resist 11 is applied to the catalyst film 3 so as to fill in the trench 2.

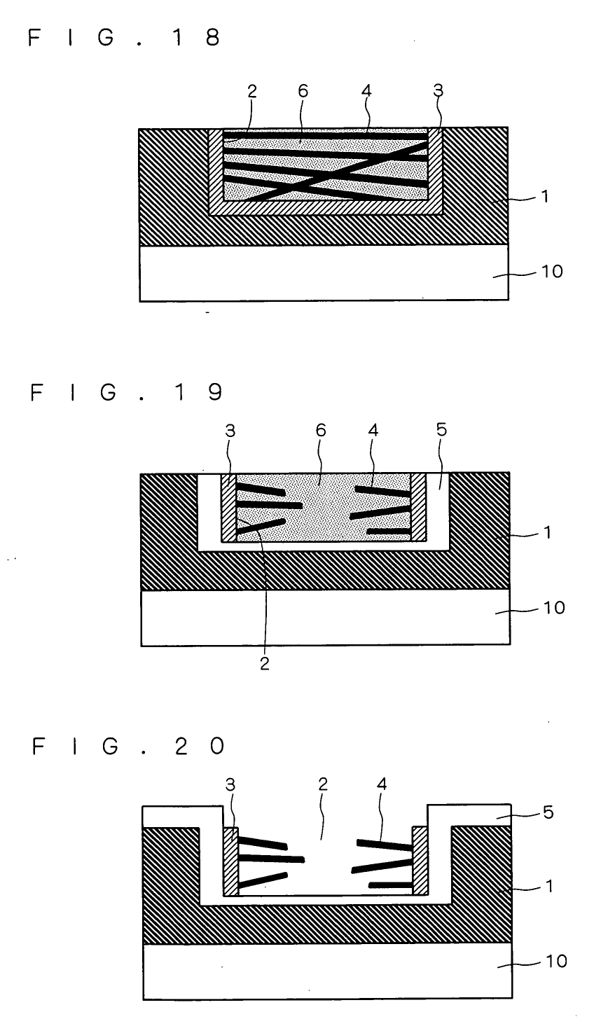

Next, etch back is carried out on the resist 11. As a result of this, as shown in FIG. 16, resist 11 remains only on the bottom of the trench 2 through the catalyst film 3.

Next, anisotropic etching is carried out using the remaining resist 11 as a mask. As a result of this, the portions of the catalyst film 3 on the upper surface of the interlayer insulating film 1 are removed. That is, as shown in FIG. 17, the catalyst film 3 remains only on the two sides and the bottom of the trench 2. Here, FIG. 17 shows a state after the resist 11 has been removed.

Next, carbon nanotubes 4 are grown on the catalyst film 3 in accordance with a thermal CVD method or the like. Here, the carbon nanotubes 4 are grown so as to reach from one surface (one catalyst film 3) to the other surface (the other catalyst film 3) of the trench 2.

Concretely speaking, as shown in FIG. 14, the carbon nanotubes 4 are formed so as to reach from one side to the other side of the trench. In addition, the carbon nanotubes 4 are formed so as to reach from the bottom to either side of the trench 2.

As a result of the aforementioned steps, a wire structure as shown in FIG. 14 is completed.

As described above, the catalyst film 3 is provided on the entirety of the inner surfaces (the two sides and the bottom) of the trench 2 having a cross section of a rectangular shape in the wire according to this embodiment. Accordingly, the carbon nanotubes 4 can be grown within the trench 2 more densely in the wire structure according to this embodiment than in the wire structure according to the first embodiment.

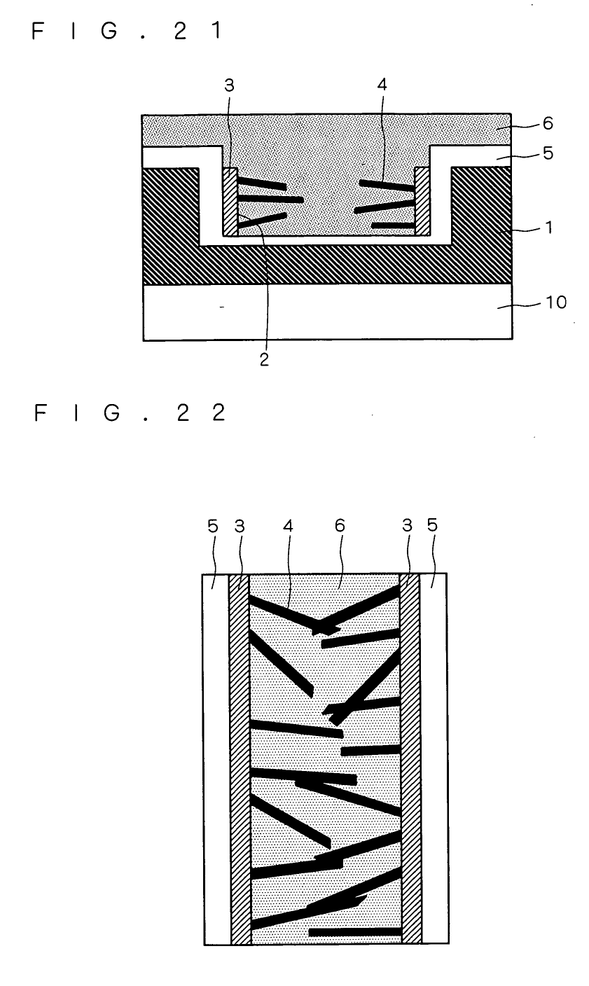

In addition, as described above, the inside of the trench 2 may be filled in with a conductor 6 (FIG. 18). As a result of this, a greater amount of current can flow through the wire. Here, as described above, a barrier film 5 may be provided between the interlayer insulating film 1 and the catalyst film 3 in order to prevent the diffusion of the conductor 6 into the interlayer insulating film 1.

### Fourth Embodiment

FIG. 19 is a perspective cross-sectional view showing a wire structure according to a fourth embodiment.

As shown in FIG. 19, the carbon nanotubes 4 that grow on the catalyst film 3 that is formed on one inner surface of the trench 2 do not reach the catalyst film 3 that is formed on the other surface in the wire structure according to this embodiment. That is, the carbon nanotubes 4 (FIG. 19) inside the wire structure according to this embodiment are not grown as much as the carbon nanotubes 4 (FIG. 8) inside the wire structure according to the second embodiment.

Here, FIG. 19 only shows a small number of carbon nanotubes 4 for the simplicity of the drawing. Actually, however, the carbon nanotubes 4 inside the trench 2 are formed more densely. Accordingly, some carbon nanotubes 4 make contact with (overlap) each other though not shown.

Thus, a current that flows through one carbon nanotube 4 also flows through another carbon nanotube 4 that makes contact with this carbon nanotube 4 through the contact between these carbon nanotubes 4.

The other configurations are the same as those in the wire structure according to the second embodiment.

Next, a manufacturing method of the wire structure according to this embodiment is concretely described with reference to the cross-sectional views showing the steps thereof.

First, a structure as shown in FIG. 10 is prepared.

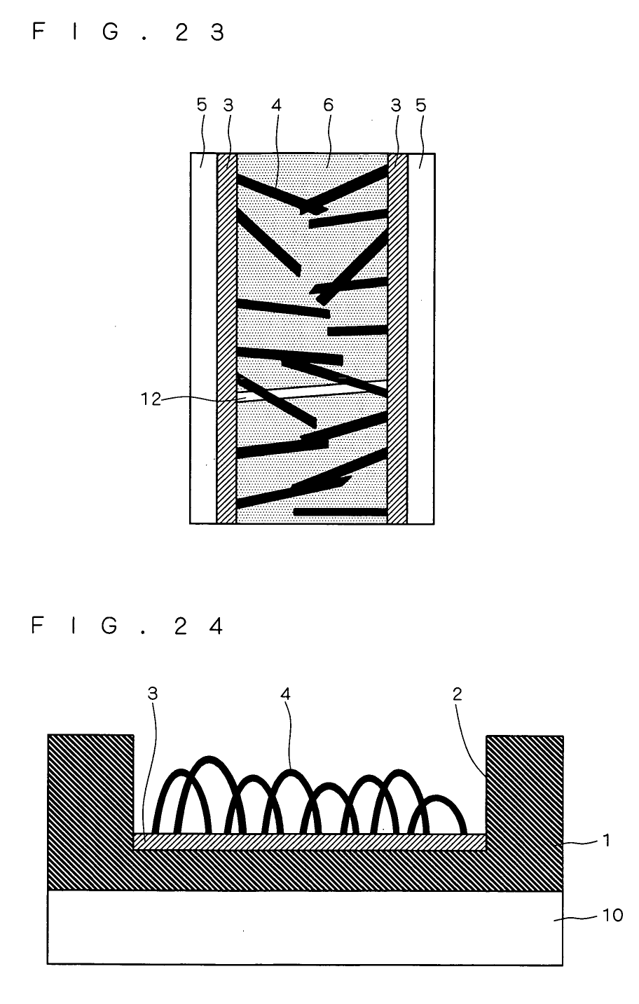

Next, as shown in FIG. 20, carbon nanotubes 4 are grown on the catalyst films 3 in accordance with a thermal CVD or the like. Here, it is necessary to make the time for growing the carbon nanotubes 4 shorter than that in the second embodiment.

As described above, the carbon nanotubes 4 that have grown on one side of the trench 2 can be made to not reach the other side by making the time for growing the carbon nanotubes 4 shorter.

Next, as shown in FIG. 21, a conductor (for example, copper) 6 is formed so as to fill in the trench 2 in which the carbon nanotubes 4 are formed in accordance with, for example, a plating method or a CVD method.

After that, a CMP process is carried out, so that the portions of the conductor 6 and the barrier film 5 which exist on the interlayer insulating film 1 are removed.

As a result of the aforementioned steps, a wire structure shown in FIG. 19 is completed.

The wire structure according to this embodiment is configured as described above, and therefore, the same effects as in the wire structure according to the second embodiment can be attained. The wire structure according to this embodiment is effective in that it can still effectively function as the wire even in the case where cracking occurs in the conductor 6 as described in the second embodiment.

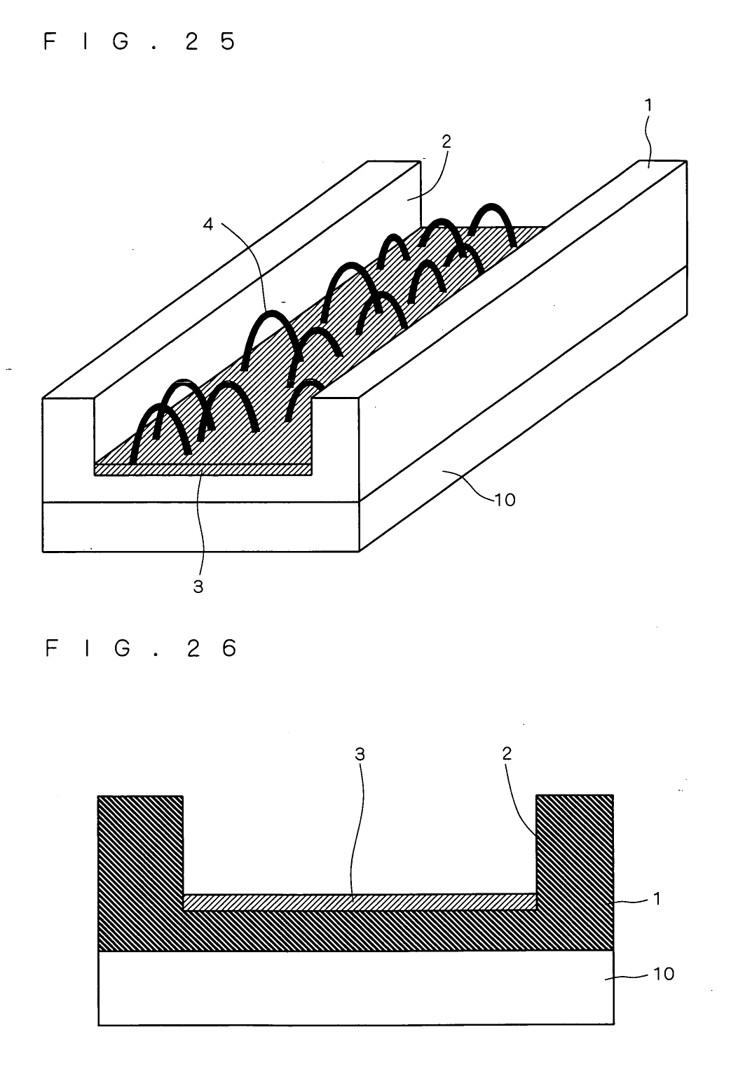

That is, it is assumed that a current flows through a wire structure where no cracking initially occurs in the wire as shown in the top view of FIG. 22.

Then, in the case where a predetermined amount or more of a current flows through this wire, a migration phenomenon occurs in the conductor 6. Thus, as a result of the occurrence of the migration phenomenon, as shown in FIG. 23, a crack 12 occurs in the wire.

However, the carbon nanotubes 4 are not affected even in the case where the crack 12 occurs in the conductor 6 as shown in FIG. 23. Here, the value of resistance of the carbon nanotubes 4 is lower than that of copper by two digits or more. Accordingly, even in the case where the crack 12 occurs, the carbon nanotubes 4 serve as a carrier of electrons; therefore, the wire functions normally.

Here, the same description can be applied to the wire structure according to the second embodiment.

As described above, the barrier film 5 can be omitted in the case where the diffusion of the conductor 6 into the interlayer insulating film 1 does not become a problem.

In addition, the catalyst films 3 are formed only on the two sides of the trench 2 in this embodiment. However, the catalyst film 3 may be provided on the two sides and the bottom of the trench 2 as in the wire structure according to the third embodiment.

### Fifth Embodiment

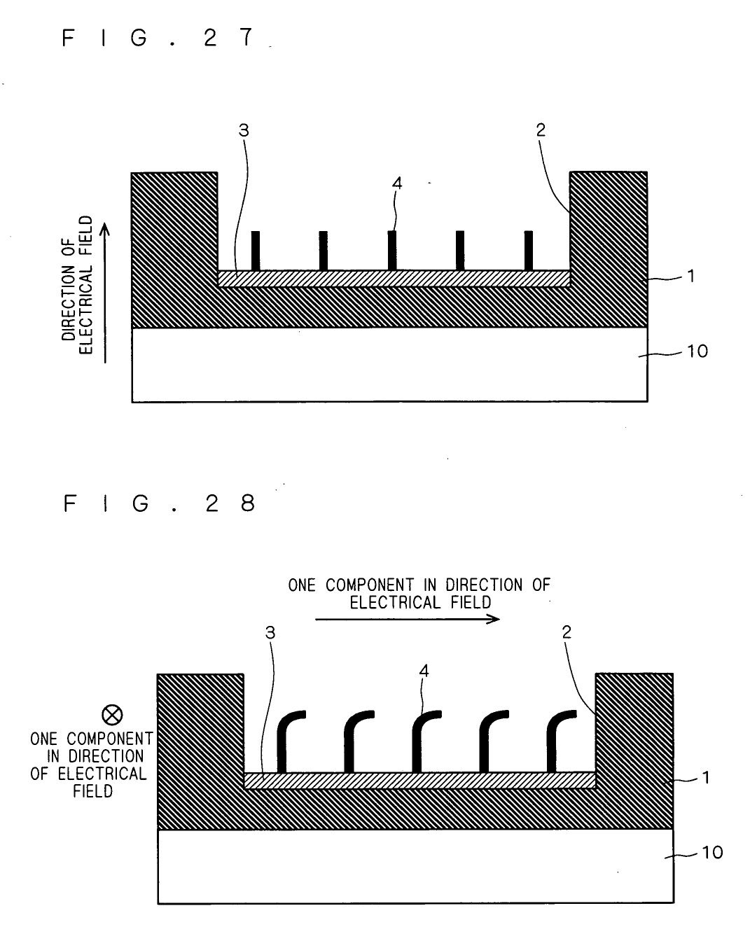

FIG. 24 is a perspective cross-sectional view showing a wire structure according to a fifth embodiment. In addition, FIG. 25 is a perspective view showing the same.

As shown in FIGS. 24 and 25, a trench 2 is formed inside the surface of the interlayer insulating film 1 that exists on a semiconductor substrate 10 in the wire structure according to this embodiment. Then, a catalyst film 3 is formed only on one inner surface (the bottom of the trench 2 in the figure) of the trench 2.

In addition, carbon nanotubes 4 grow on this catalyst film 3 so as to form an inverted U shape. That is, the carbon nanotubes 4 grows on the catalyst film 3 that exists on the bottom of the trench 2 so as to reach a different place on the same catalyst film 3.

Next, a manufacturing method of the wire structure according to this embodiment is concretely described with reference to the cross-sectional views showing the steps thereof.

First, a structure shown in FIG. 16 is prepared.

Next, isotropic etching is carried out using the remaining resist 11 as a mask. As a result of this, the portions of the catalyst film 3 that have been formed on the upper surface of the interlayer insulating film 1 as well as the two sides of the trench 2 are removed. That is, as shown in FIG. 26, the catalyst film 3 remains only on the bottom of the trench 2. Here, FIG. 26 shows a state after the resist 11 has been removed.

Next, carbon nanotubes 4 are grown on the catalyst film 3 in accordance with a thermal CVD method or the like. Here, an electrical field is applied in the direction as shown below during the process in accordance with the thermal CVD method.

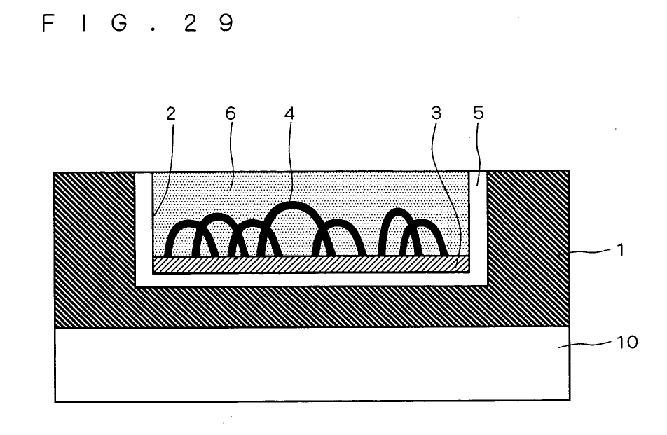

That is, as shown in FIG. 27, an electrical field is applied in the direction from the bottom to the top in the figure at the initial stage of the process for growing the carbon nanotubes 4. As a result of this, as shown in FIG. 27, the carbon nanotubes 4 grow in the upward direction on the catalyst film 3 that exists on the bottom of the trench 2.

Next, as shown in FIG. 28, an electrical field having a component in the direction from the front to the back of the figure (the direction in which the wire is provided) and a component in the lateral direction of the figure, is applied. Here, an electrical field is applied also in the lateral direction of the figure (FIG. 28) in accordance with a manufacturing method according to this embodiment. However, an electrical field may be applied only in the direction from the front to the back of the figure.

As a result of this, as shown in FIG. 28, the carbon nanotubes 4 that have grown in the upward direction of the figure start inclining in the horizontal direction of the figure while growing (concretely speaking, the lateral direction of the figure and the direction in which the wire is provided, which are hereinafter referred to as a horizontal direction). Then, the carbon nanotubes 4 keep growing in the horizontal direction of the figure.

Finally, an electrical field is applied in the direction from the top to the bottom of the figure. As a result of this, the carbon nanotubes 4 that have grown in the horizontal direction of the figure start declining in the downward direction of the figure while growing. Then, the carbon nanotubes 4 keep growing in the downward direction of the figure, and these carbon nanotubes 4 reach the catalyst film 3 that exists on the bottom of the trench 2.

As a result of the aforementioned steps, a wire structure as shown in FIGS. 24 and 25 is completed.

It is needless to say that the wire structure according to this embodiment naturally has the same effects as in the wire structure according to the first embodiment.

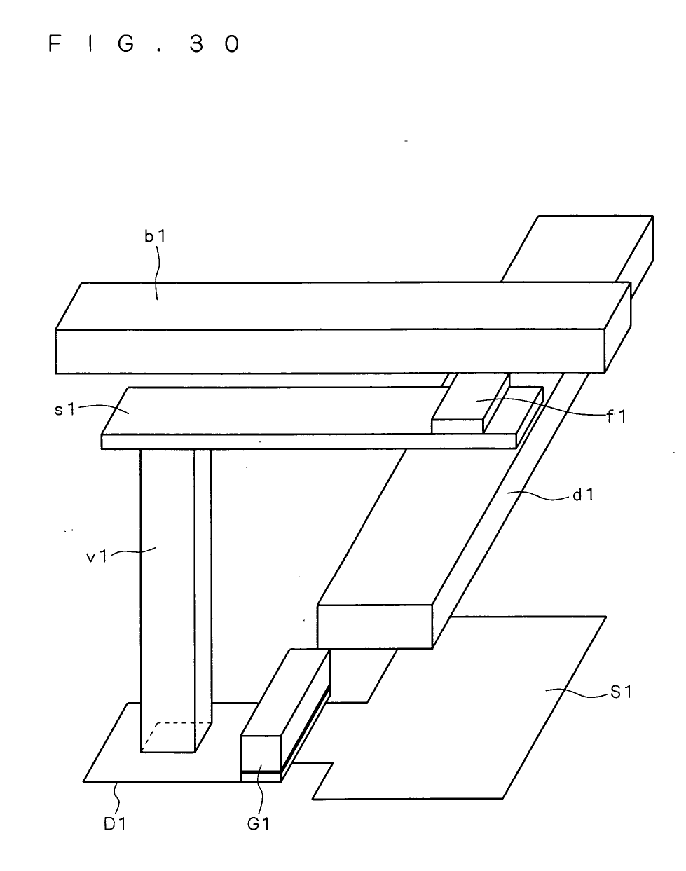

Here, the trench 2 may be filled in with a conductor in a wire structure as shown in FIGS. 24 and 25. In addition, in the case where the diffusion of the conductor into the interlayer insulating film 1 occurs, a barrier film 5 may be provided between the conductor 6 and the interlayer insulating film 1 as shown in FIG. 29.

In addition, the configuration where the catalyst film 3 is provided only on the bottom of the trench 2 is described according to this embodiment. However, it is not necessary to limit the wire structure to this, but the wire may be formed by providing the catalyst film 3 on either side of the trench 2.

### Sixth Embodiment

In recent years, the development of an MRAM (Magnetoresistive Random Access Memory) that is formed inside a semiconductor device has been actively progressive. FIG. 30 shows the configuration of the major portions of such an MRAM.

As shown in FIG. 30, a bit line b1 and a digit line d1 are provided in different levels so as to cross each other (in a plan view) in the MRAM. In addition, a strap s1 and an MTJ (Magnetro Tunneling Junction) film f1 intervene between the bit line b1 and the digit line d1 in the region where the bit line b1 and the digit line cross each other.

In addition, a transistor is formed of a drain region D1, a gate electrode G1, and a source region S1 on a semiconductor substrate. In addition, a via v1 for connecting the strap s1 to the drain region D1, and a via (not shown) for connecting the MTJ film f1 to the bit line b1, are provided. Here, the gate electrode G1 includes an insulating film (the black portion in the gate electrode G1).

In an MRAM shown in FIG. 30, currents in predetermined directions are made to flow through the bit line b1 and the digit line d1 respectively. Then, magnetic fields are generated around the respective lines b1 and d1 in accordance with the directions of these currents. Thus, the direction of the spin in the MTJ film f1 is changed (write in) by a synthesized magnetic field from the magnetic field that is generated around the bit line b1 and the magnetic field that is generated around the digit line d1.

In addition, a current in a predetermined direction is made to flow through the bit line b1. Then, an amount of current that is determined in accordance with the direction of the spin of the MTJ film f1 flows through the MTJ film f1. Thus, the current that has flown via the MTJ film f1 flows into the drain region D1 via the strap s1 and the via v1. Then, the connecting/blocking of a current into the source region S1 is controlled (read out) through the operation for turning on/off the gate electrode G1.

It is necessary to make a current of about mA order flow through a bit line b1 and a digit line d1 that form an MRAM for carrying out such an operation. However, further miniaturization of semiconductor devices has progressed in recent years. Accordingly, the wires have naturally been miniaturized (downsized).

It is necessary to increase the current density of a current that flows through such wires as those that have been downsized as described above in order to maintain the same amount of current (current of about mA order) as before. However, in the case where a conventional wire such as a copper wire is adopted, a migration phenomenon or fusion cutting occurs in the wire as described above.

However, any of the wire structures according to the present invention can be adopted for a bit line b1 or a digit line d1, so that a current having a higher current density (10⁹ A/cm² or more) can be made to flow through each wire (wires that include at least carbon nanotubes 4) according to the present invention. That is, even in the case where the miniaturization of the structure, for example, has progressed, the amount of the current that flows through the wires can be maintained and a problem of wire defects such as disconnection does not occur.

In addition, the wire structure according to the third embodiment (the structure where the catalyst film 3 is provided on the two sides and the bottom of the trench 2) is adopted in a bit line b1 and a digit line d1, and furthermore, a magnetic material is adopted for the catalyst film 3, so that the effects shown below can be attained.

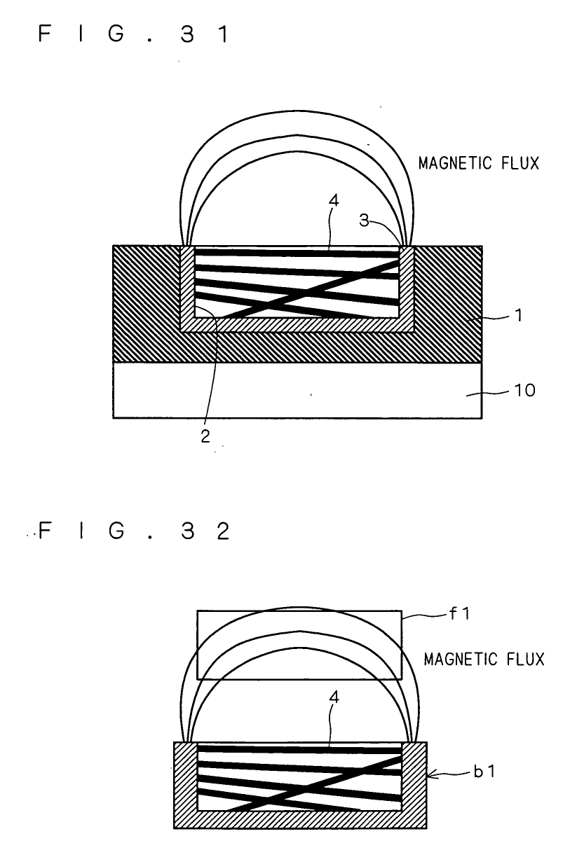

That is, a wire (which is referred to as wire P) where the two sides and the bottom of the trench 2 are covered with a catalyst film 3 that is a magnetic material is formed. As a result of this, as shown in FIG. 31, the occurrence of a magnetic field from the periphery of the wire except for the upper surface of this wire can be suppressed (shield effect).

Furthermore, the intensity of the magnetic field that occurs from the upper surface of the wire can be increased to about two times higher than that of the magnetic field that occurs from a wire (which is referred to as wire X) of which the surroundings are not covered with a catalyst film 3 that is a magnetic material. In other words, only half of the amount of current that flows through a wire X is required to flow through a wire P in order for the same intensity of magnetic fields to occur in the surroundings of the wires.

Here, the aforementioned shield effect and the effect of increasing the magnetic field which are attained by covering a copper wire with a ferromagnetic material are reported in, for example, “A 1-Mbit MRAM Based on 1T1MTJ Bit Cell Integrated with Copper Interconnects” (IEEE JOURNAL OF SOLID-STATE CIRCUIT, Vol. 38, No. 5, May 2003) and the like.

Accordingly, the structure of a wire P is adopted for a digit line d1 and an MTJ film f1 is provided so as to face the surface of this digit line d1 that is not covered with the catalyst film 3 as shown in the cross-sectional view of FIG. 32.

As a result of this, other MTJ films (not shown) which are adjacent to the MTJ film f1 that is shown can be prevented from being subject to the influences of the magnetic field that occurs from the digit line d1 that is shown.

Furthermore, a stronger magnetic field is applied to the MTJ film f1 that is shown with the same amount of current than in a case where a wire X is adopted for the digit line d1. In other words, only half the amount of current that flows through the digit line d1 for which a wire X is adopted and can be made to flow through the digit line d1 for which a wire P is adopted in order to apply magnetic fields of the same intensity to MTJ film f1.

Here, a case where a wire P is adopted for a digit line d1 is described above. However, the same argument can naturally be made in a case where a wire P is adopted for a bit line b1. Here, the catalyst film is formed on the walls on the two sides and the top in the bit line b1.

In addition, the aforementioned effects are increased by adopting a ferromagnetic material such as cobalt, nickel, or iron as the catalyst film 3.

In addition, a case where a wire structure shown in FIG. 14 is adopted for a digit line d1 is described in the above. However, a wire (FIG. 18) where the aforementioned wire is filled in with a conductor (for example, copper) 6 may be adopted for a digit line d1 and all of the aforementioned effects can be attained in the configuration where the wire is filled in with a conductor 6.

In addition, a wire that is fabricated in accordance with the following manufacturing method may be adopted for a digit line d1 or the like.

First, a structure shown in FIG. 6 is prepared. Here, a catalyst film 3 is made of a magnetic material (preferably a ferromagnetic material).

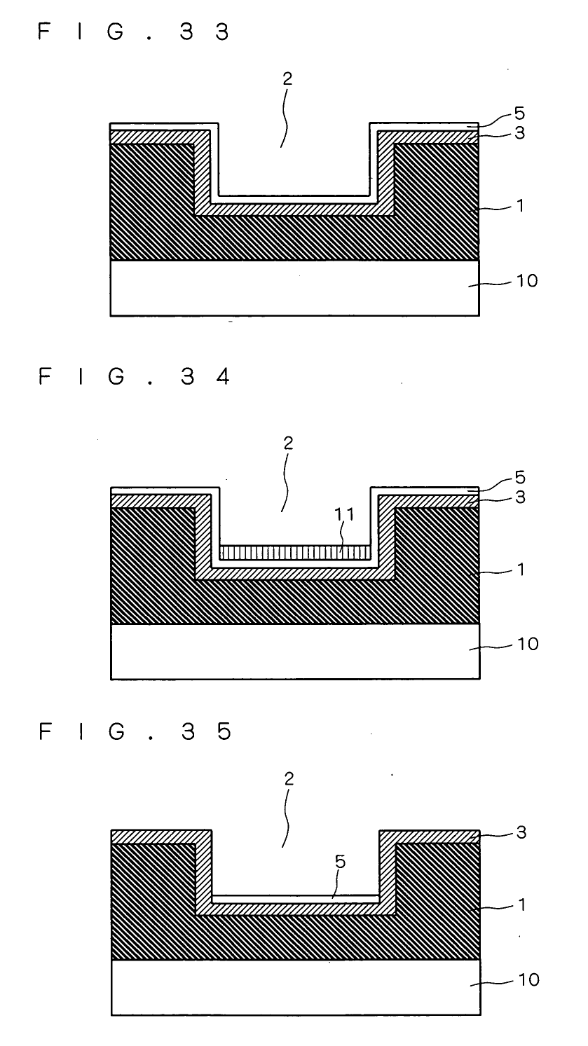

Next, as shown in FIG. 33, a barrier film 5 having a predetermine film thickness is formed on the catalyst film 3 in accordance with, for example, a sputtering method. Here, the barrier film 5 is made of tantalum, tantalum nitride or the like, and is a growth suppressing film which has the function of suppressing the growth of carbon nanotubes 4 on the catalyst film 3.

Next, a resist 11 is applied to the barrier film 5 so as to fill in the trench 2. After that, etch back is carried out, so that the resist 11 remains only on the bottom of trench 2 as shown in FIG. 34.

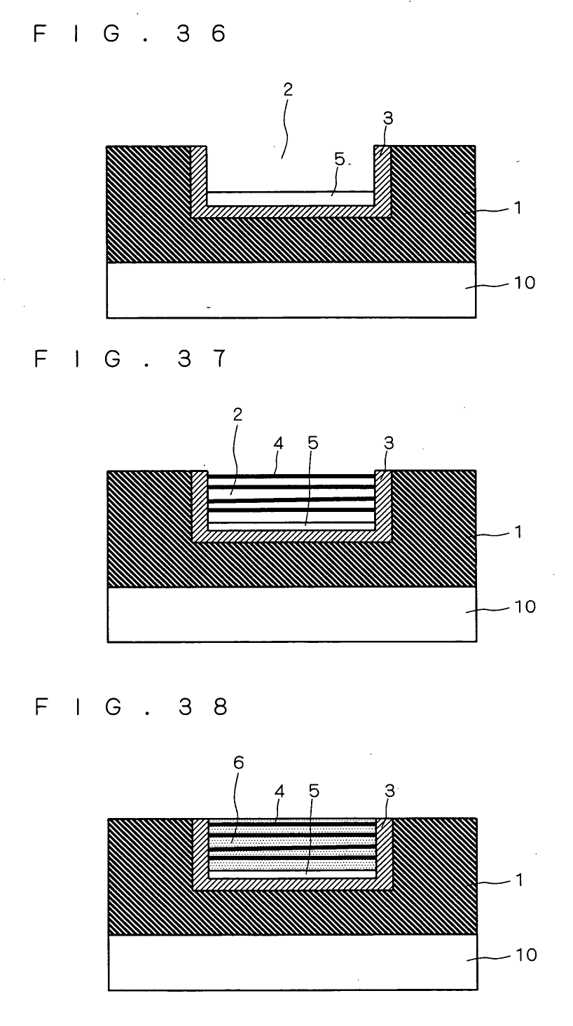

Next, the resist 11 is utilized as a mask and isotropic etching is carried out on the barrier film 5. As a result of this, the barrier film 5 is partially removed. Then, as shown in FIG. 35, the barrier film 5 remains only on the bottom of the trench 2 via the catalyst film 3.

Next, the barrier film 5 is utilized as a mask, and anisotropic etching is carried out on the catalyst film 3. As a result of this, the portions of the catalyst film 3 on the upper surface of the interlayer insulating film 1 are removed. Then, as shown in FIG. 36, the catalyst film 3 remains only on the two sides and the bottom of the trench 2.

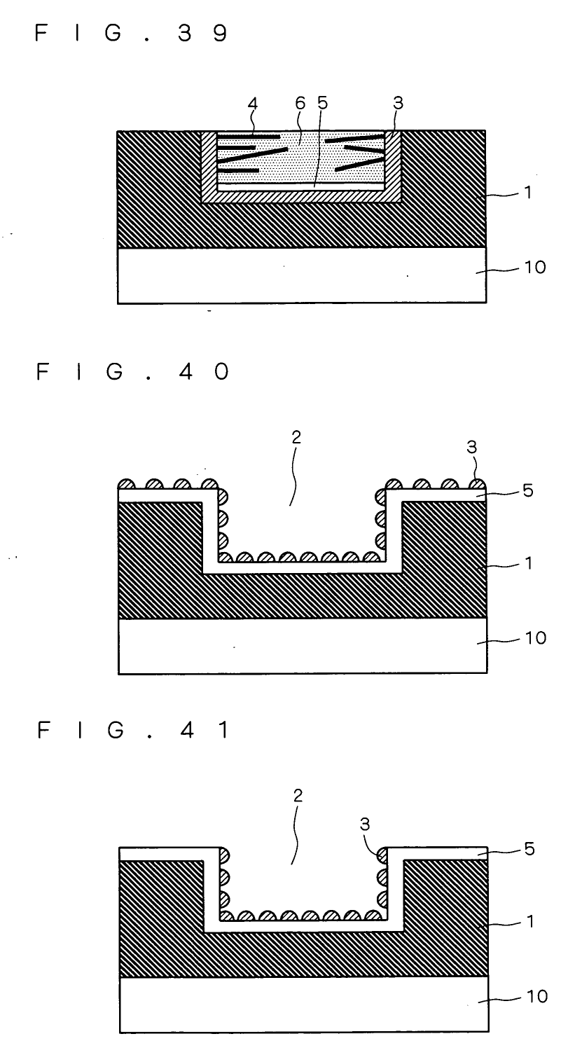

After that, as shown in FIG. 37, carbon nanotubes 4 are grown inside the trench 2 in accordance with a thermal CVD method. Here, the carbon nanotubes 4 are formed so as to link between the catalyst film 3 formed on the two sides.

Here, a barrier film (a growth suppressing film having the function of suppressing the growth of the carbon nanotubes 4 on the catalyst film 3) is formed on the catalyst film 3 that is formed on the bottom of the trench 2.

Accordingly, the growth of the carbon nanotubes 4 on the bottom of the trench 2 can be suppressed. As a result of this, the carbon nanotubes 4 can be easily grown between the two sides of the trench 2 since the growth on the bottom is suppressed.

A wire structure as shown in FIG. 37 that has been formed in the aforementioned steps may be adopted for a digit line d1 or the like.

In addition, a wire structure (FIG. 38) where the trench 2 of a wire shown in FIG. 37 is filled with a conductor 6 can be adopted for a digit line d1. In addition, as described in the fourth embodiment, a wire structure (FIG. 39) where carbon nanotubes 4 that have grown on the catalyst film 3 formed on one inner side of the trench 2 do not reach the catalyst film 3 formed on the other inner side can be adopted. Here, in either case, the catalyst film 3 is made of a magnetic material (preferably a ferromagnetic material).

### Seventh Embodiment

In the following, another method for manufacturing a wire that at least includes carbon nanotubes is described.

First, a structure shown in FIG. 5 is prepared.

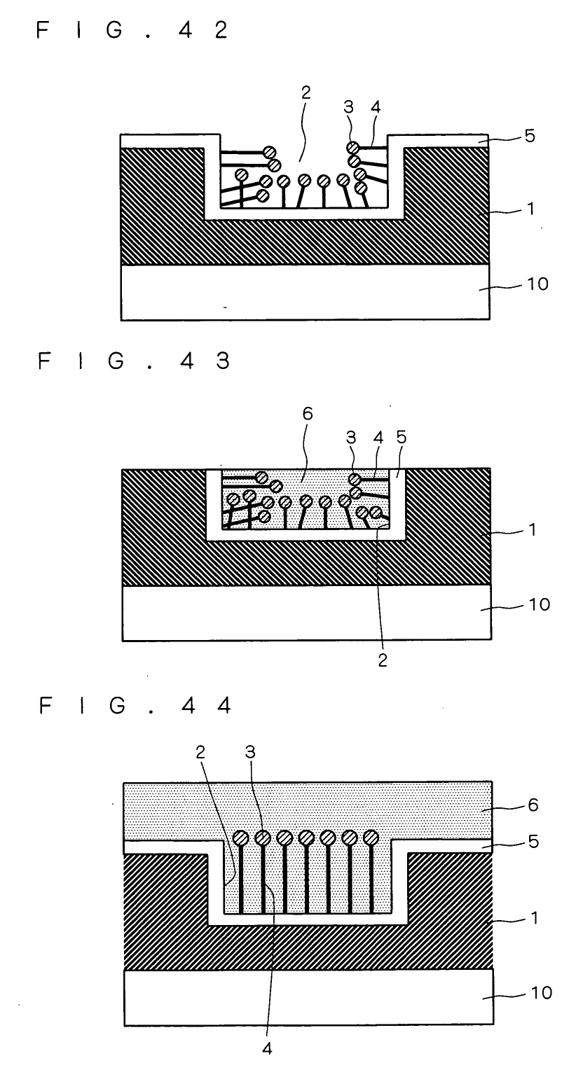

Next, as shown in FIG. 40, a barrier film 5 is formed on the two sides and the bottom of the trench 2 and on the upper surface of the interlayer insulating film 1 in accordance with, for example, a sputtering method. Next, as shown in FIG. 40, a number of catalyst films 3 in island form (dot form) are formed on the barrier film 5 in accordance with, for example, a sputtering method.

Here, the time for sputtering is set so that the sputtering can be stopped at a stage where the catalyst films 3 starts growing. As a result of this, a number of catalyst films 3 in island form can be formed.

In addition, heat treatment may be carried out after the formation of a thin catalyst film 3 on the barrier film 5. As a result of this, the catalyst film 3 aggregates, so that a number of catalyst films 3 in island form are formed.

Next, some catalyst films 3 are removed in accordance with an etch back method or the like using a resist. As a result of this, as shown in FIG. 41, catalyst films 3 in island form remain only on the two sides and the bottom of the trench 2 through the barrier film 5.

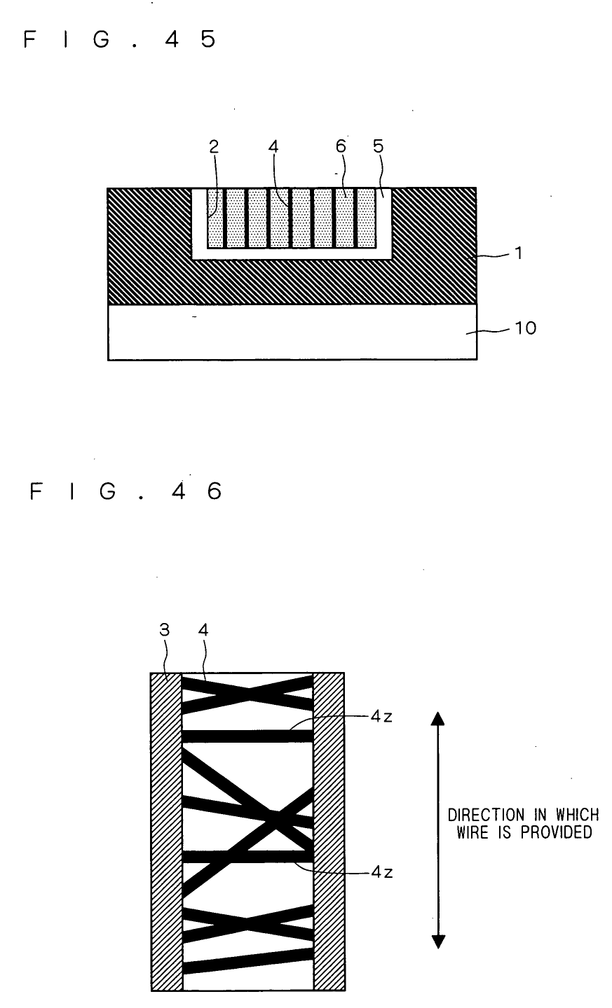

Next, as shown in FIG. 42, carbon nanotubes 4 are grown in accordance with a plasma CVD method or the like. Here, the carbon nanotubes 4 are grown in a state where the catalyst films 3 in island form are attached to the tip ends of the carbon nanotubes 4. The carbon nanotubes 4 grow in the state where the catalyst films 3 in island form are attached to the tip ends of the carbon nanotubes 4 in accordance with, for example, a plasma CVD method.

After that, as shown in FIG. 43, a conductor (for example, copper) 6 is formed on the barrier film 5 in accordance with a plating method, or the like so as to fill in the trench 2. Furthermore, as shown in FIG. 43, the portions of the barrier film 5 and the conductor 6 on the interlayer insulating film 1 are removed by means of CMP or the like. As a result of this, the barrier film 5 and the conductor 6 remain only inside the trench 2.

A wire structure according to the present invention can be fabricated also in accordance with the aforementioned method. Thus, a current having a large current density can flow also in the case of a wire structure shown in FIG. 43. In addition, even in the case where cracking occurs in a portion of the conductor 6 due to a migration phenomenon, the carbon nanotubes 4 are not affected by such cracking; therefore, a wire structure shown in FIG. 43 is highly reliable for a wire.

Here, in some cases, it is more preferable for the catalyst film 3 (impurities) such as iron not to remain on the sides and the bottom of the trench 2 after the formation of the carbon nanotubes. This is because impurity particles such as remaining iron partially pass through the interlayer insulating film 1 so as to provide a junction to the wafer substrate, causing the occurrence of a junction leak.

Therefore, catalyst films 3 are formed in an island form and carbon nanotubes 4 are grown in a state where these catalyst films 3 are attached to the tip ends of the carbon nanotubes 4 (carbon nanotubes 4 are grown, for example, in accordance with a plasma CVD method) as in a manufacturing method according to this embodiment.

As a result of this, the catalyst films 3 can be prevented from being attached to a side or the like of the trench in the completed wire structure. Accordingly, there is no possibility of a junction leak as described above.

### Eighth Embodiment

A manufacturing method according to this embodiment is a modification of the manufacturing method according to the seventh embodiment.

Here, in the seventh embodiment, a case is described where catalyst films 3 in island form are formed on the two inner sides and the bottom of the trench 2 (FIGS. 40 to 43).

In accordance with the manufacturing method according to this embodiment, however, catalyst films 3 in island form are formed only on one inner surface (for example, on the bottom) of the trench 2, and after that, carbon nanotubes 4 are grown.

First, a structure as shown in FIG. 5 is prepared.

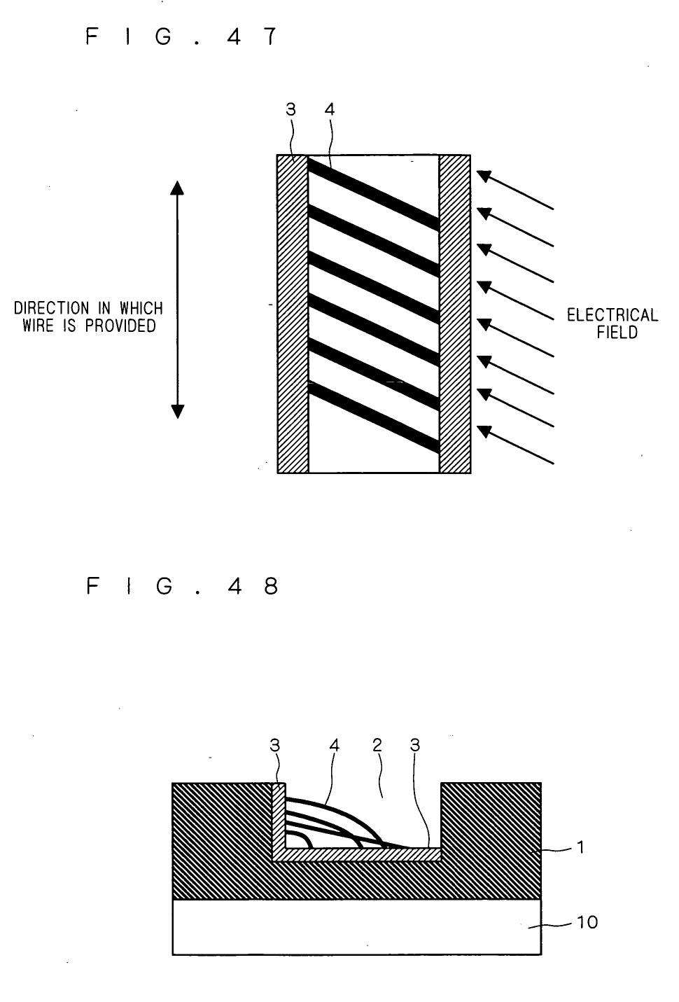

Next, as shown in FIG. 44, a barrier film 5 is formed on the two inner sides and the bottom of the trench 2 as well as on the interlayer insulating film 1. After that, catalyst films 3 in island form are formed only on the bottom of the trench 2 in accordance with the method that is described in the seventh embodiment.

Next, as shown in FIG. 44, carbon nanotubes 4 are grown in accordance with a plasma CVD method or the like. Here, the carbon nanotubes 4 are grown in a state where the catalyst films 3 are attached to the tip ends of the carbon nanotubes 4. In addition, the carbon nanotubes 4 grow in the direction from the bottom to the top in the figure (FIG. 44).

Next, a conductor 6 such as copper is deposited on the barrier film 5 in such a manner as to fill in the trench 2. FIG. 44 shows this state.

Next, a CMP process is carried out on a structure as that shown in FIG. 44. As a result of this, as shown in FIG. 45, the portions of the barrier film 5 and the conductor 6 on the interlayer insulating film 1 are removed. Here, as shown in FIG. 45, the catalyst films 3 that have been attached to the tip ends of the carbon nanotubes 4 are removed together with the aforementioned conductor 6 and the like.

Here, catalyst films 3 in island form may be provided on any inner surface of the trench 2. In the case where the catalyst films 3 are provided only on the bottom of the trench 2 as described above and a process is carried out in accordance with the aforementioned manufacturing method, however, the catalyst films 3 can be completely removed from the wire structure.

It is assumed that an electrical field is applied when the carbon nanotubes 4 are grown. Then, the carbon nanotubes 4 grow in the direction of this electrical field.

Accordingly, in the case where the carbon nanotubes 4 are grown in the direction from the bottom to the top of the trench 2 in accordance with this embodiment, the carbon nanotubes 4 may be grown while applying an electrical field in such a direction.

In addition, in the case where an electrical field is applied, it is preferable for the applied electrical field to have a component in the direction in which the wire is provided (the trench 2 is formed). In FIG. 45, for example, an electrical field in a direction made up of a component in the direction from the bottom to the top in the figure and a component in the direction from the front to the rear in the figure (a component in the direction in which the trench 2 extends) is applied.

This is because the carbon nanotubes 4 grow in the direction having the aforementioned component in which the trench 2 extends by applying an electrical field having a component in such direction. Thus, a wire having carbon nanotubes 4 that have grown in such direction is smaller in the average electrical resistance than a wire having carbon nanotubes 4 that have grown without having the aforementioned component in the direction in which the trench 2 extends.

### Ninth Embodiment

A manufacturing method according to a ninth embodiment has a feature in that an electrical field is applied in a predetermined direction when carbon nanotubes 4 are grown.

As described above, in the case where an electrical field is applied when carbon nanotubes 4 are grown, the carbon nanotubes 4 grow in the direction of this electrical field. Then characteristics are utilized in the manufacturing method according to this embodiment.

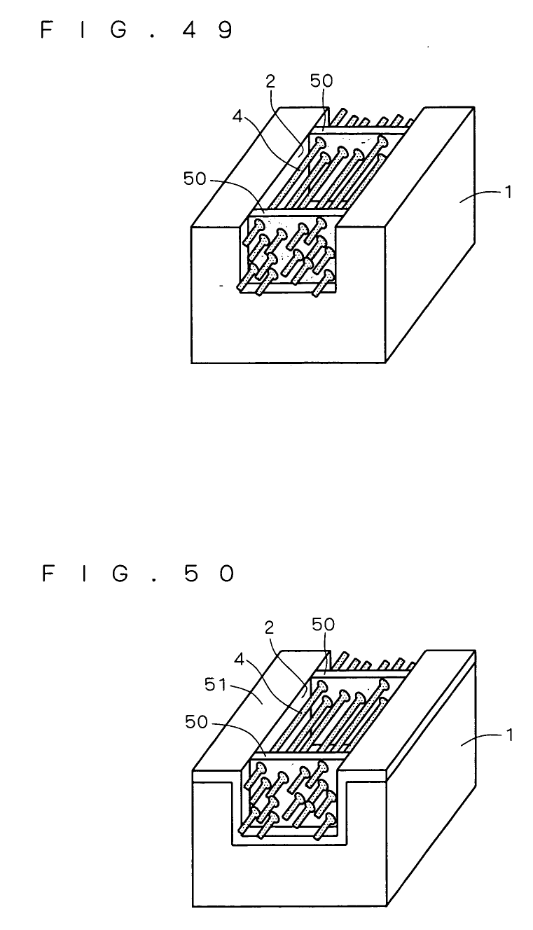

In the case where carbon nanotubes 4 are grown without an application of an electrical field, the carbon nanotubes 4 are usually formed in different directions as shown in FIG. 46.

However, there is a possibility that some carbon nanotubes 4z that grow in the direction perpendicular to the direction in which the wire is provided (in the direction in which the trench 2 extends) exist from among a great number of carbon nanotubes 4. That is, the carbon nanotubes 4z are formed in the direction of the normal of the sides of the trench 2.

Thus, in the case where the carbon nanotubes 4z that are formed in the aforementioned direction are included, the resistance of the entire wire becomes high in comparison with the resistance of the entire wire which has no carbon nanotubes 4z. This occurs because of the following reasons.

It is assumed that carbon nanotubes 4z grow in the direction perpendicular to the direction in which the trench 2 extends and these carbon nanotubes 4 link between the catalyst film 3 that exists on the two sides of the trench 2. Then, no difference in the potential occurs between one end and the other end of the carbon nanotubes 4z even when a voltage is applied in the direction of the wire (in the direction in which the trench 2 extends).

This means that there is no flow of current through the carbon nanotubes 4z. Accordingly, the more carbon nanotubes 4z are included, the higher the resistance of the entire wire having the same density of the carbon nanotubes becomes.

Therefore, as shown in FIG. 47, an electrical field having a component in the direction in which the wire is provided (a component in which the trench 2 extends) is applied in accordance with the manufacturing method according to this embodiment.

Then, as shown in FIG. 47, the carbon nanotubes 4 grow in the direction of this electrical field. That is, a wire that does not include carbon nanotubes 4z which grow in the direction perpendicular to the direction in which the trench 2 extends can be provided.

Accordingly, the resistance of the entire wire that is fabricated in accordance with the method according to this embodiment can further be reduced in comparison with a wire that includes carbon nanotubes 4z which are formed in the aforementioned direction.

Here, the greater the inclination of the carbon nanotubes 4 from the direction of the normal of the sides of the trench 2 becomes, the greater the difference in the potential between one end and the other end of these carbon nanotubes 4 becomes in the case where a voltage is applied in the direction in which the trench 2 extends.

Accordingly, a current more easily flows through the carbon nanotubes 4 in the aforementioned case. That is to say, the greater the inclination of the carbon nanotubes 4 from the direction of the normal of the sides of the trench 2 becomes, the further the resistance value of the entire wire can be reduced.

The aforementioned wire structures according to the present invention have a feature in that carbon nanotubes 4 are at least included in the wire. Accordingly, any wire structure that includes carbon nanotubes 4 other than those in the aforementioned embodiments may be possible.

A wire structure shown in FIG. 48 is, for example, possible as a wire structure that includes carbon nanotubes 4 in addition to the wire structures shown in the aforementioned embodiments.

That is, as shown in FIG. 48, a catalyst film 3 may be formed on one side and the bottom of the trench 2 and carbon nanotubes 4 may be grown between the catalyst film 3 on the side and on the bottom in the configuration of the wire.

In addition, in the case where a wire structure according to the present invention is applied to a semiconductor device, a problem of an increase in the current density in the wires together with the miniaturization of the semiconductor device can be solved as described above.

### Tenth Embodiment

FIG. 49 is an enlarged perspective view showing the wire structure according to a tenth embodiment.

As shown in FIG. 49, an interlayer insulating film 1 is formed on a semiconductor substrate (not shown). In addition, a trench 2 having a cross section of a substantially rectangular shape is formed inside the surface of the interlayer insulating film 1.

In addition, a plurality of partitioning conductive films 50 are formed inside the trench 2 in the wire structure according to this embodiment (FIG. 49 shows two partitioning conductive films 50). The intervals between the respective partitioning conductive films 50 are, for example, about several microns.

Here, as shown in FIG. 49, these partitioning conductive films 50 are provided so as to partition the trench 2 along the direction in which this trench 2 extends. In addition, in this embodiment, these partitioning conductive films 50 are provided (formed) at equal intervals inside the trench 2 (in another example of the configuration, a structure where partitioning conductive films 50 are not provided at equal intervals is possible).

In addition, these partitioning conductive films 50 at least include a catalyst metal that becomes the core of the growth of the carbon nanotubes 4 as a component. The partitioning conductive films 50 themselves may naturally be made of such a catalyst (film). The partitioning conductive films 50 which are catalyst films may be, for example, made of cobalt (Co), iron (Fe), nickel (Ni), tungsten (W) or a compound that includes these.

Furthermore, as shown in FIG. 49, the carbon nanotubes 4 are formed so as to connect the aforementioned partitioning conductive films 50 to each other.

Here, the number of carbon nanotubes 4 that exist between these partitioning conductive films 50 is great. In addition, as shown in FIG. 49, the carbon nanotubes 4 are formed in the direction, including a component in the direction in which the trench 2 extends (in FIG. 49, the carbon nanotubes 4 are formed substantially parallel to the direction in which the trench extends). Here, the carbon nanotubes 4 grow while holding the catalyst metal at the tip ends thereof (one or the other end of the carbon nanotubes 4).

Here, in the case where carbon nanotubes 4 are used as a wire according to the present invention, it is desirable for the carbon nanotubes 4 to be formed as multiple wall carbon nanotubes. This is because multiple wall carbon nanotubes are higher in conductivity than single layer carbon nanotubes.

In FIG. 49, a plurality of carbon nanotubes 4 grow in the same direction. However, it is not necessary for the carbon nanotubes 4 to grow in the same direction. In the case where an electrical field, for example, is applied when the carbon nanotubes 4 grow, the carbon nanotubes 4 which are aligned in the direction of this electrical field are formed. In the case where such an electrical field is not applied, however, the carbon nanotubes 4 usually grow in a variety of directions.

As described above, the carbon nanotubes 4 form a current path in this embodiment (that is, in a wire structure having carbon nanotubes 4 that have grown in the direction in which the trench 2 extends between the partitioning conductive films 50 that are formed inside the trench 2).

Accordingly, the same effects as those described, for example, in the first embodiment can be attained in the wire structure according to this embodiment. That is, effects such as reduction in the resistance of the wire, an increase in the current density, restriction of fusion cutting of the wire and suppression of the occurrence of a migration can be attained as described above because of the characteristics of the carbon nanotubes 4.

In addition, it is assumed that the partitioning conductive films 50 are formed of catalyst films that become the core of the growth of carbon nanotubes 4. In this case, the carbon nanotubes 4 can be easily grown only by providing these partitioning conductive films 50.

In addition, the partitioning conductive films 50 are formed at equal intervals inside the trench 2. Accordingly, the time for the carbon nanotubes 4 to reach the adjacent partitioning conductive films 50 from the start of the growth is approximately the same in each space between the partitioning conductive films 50. That is, the control of the formation of these carbon nanotubes 4 between the partitioning conductive films 50 becomes easier.

Here, in the wire structure according to this embodiment, copper is not used; therefore, a barrier film having the function of preventing the diffusion of copper is not provided. Accordingly, a current having a greater current density can be made to flow and carbon nanotubes 4, which have a low resistance, can be formed densely within the entire volume of the trench 2. That is, approximately the entire volume in the trench 2 can be utilized as a current path by the carbon nanotubes 4. Namely, an increase in the limited amount of the current that flows through the wire and reduction in the resistance of the wire having such a structure can be achieved.

### Eleventh Embodiment

FIG. 50 is an enlarged perspective view showing a wire structure according to an eleventh embodiment.

As shown in FIG. 50, the wire structure according to this embodiment is approximately the same as the wire structure according to the tenth embodiment. However, the two wire structures are different in the following point.

In the wire structure according to this embodiment, as shown in FIG. 50, a first barrier film 51 is formed inside the trench 2 (at least on the sides and the bottom of the trench 2). Here, the first barrier film 51 is a film used for suppressing (preventing) the diffusion of a catalyst from a partitioning conductive film 50 into the interlayer insulating film 1. Silicon nitride (SiN), tantalum nitride (TaN), or the like can be adopted as this first barrier film 51.

The other configurations are the same as those in the tenth embodiment; therefore, the descriptions thereof are herein omitted.

As described above, the first barrier film 51 is formed in the wire structure according to this embodiment. Accordingly, the diffusion of a catalyst (for example, cobalt, nickel, iron, or the like) from the partitioning conductive film 50 to the interlayer insulating film 1 can be suppressed (prevented).

### Twelfth Embodiment

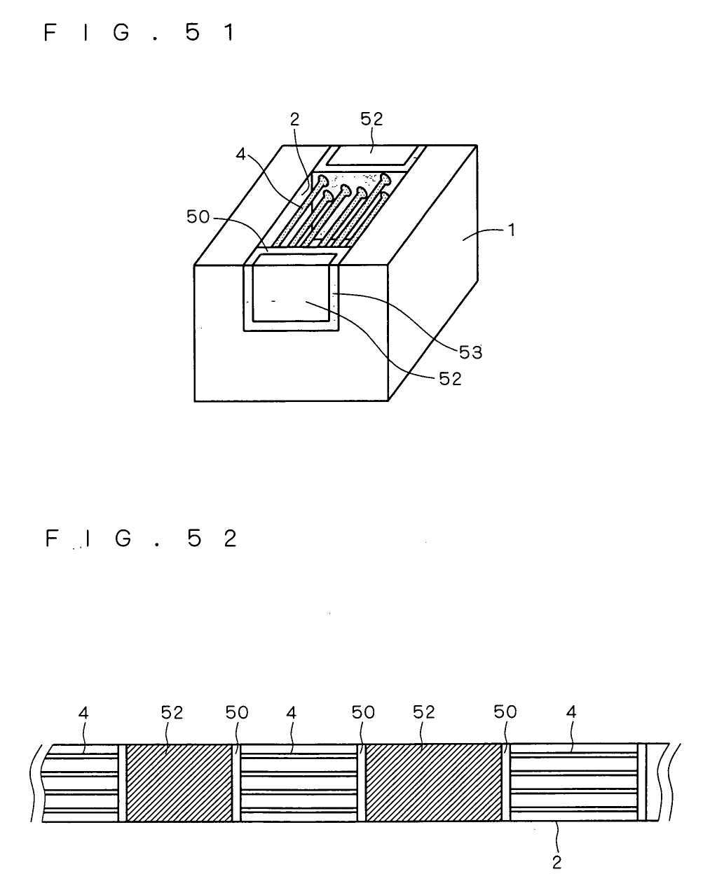

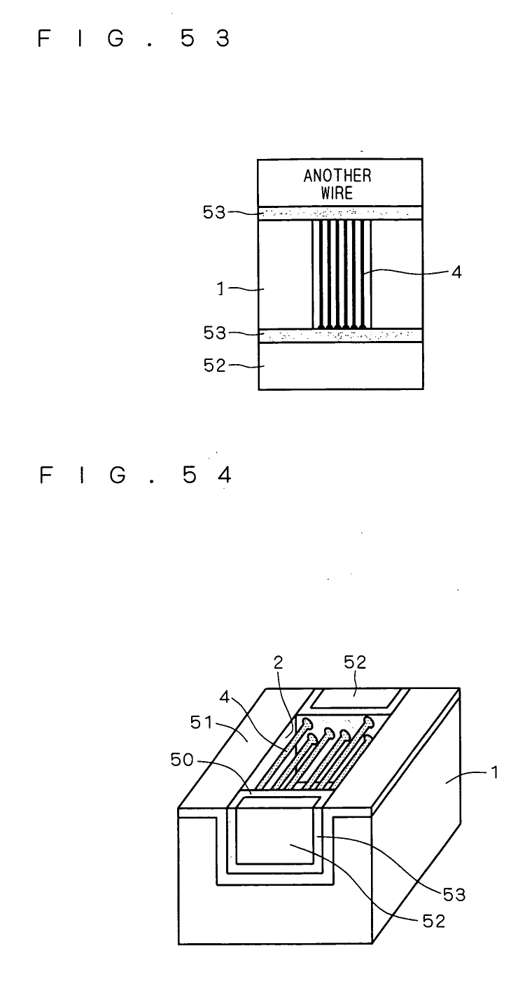

FIG. 51 is an enlarged perspective view showing a wire structure according to a twelfth embodiment. In addition, FIG. 52 is a schematic plan view showing the wire structure according to this embodiment.

As shown in FIG. 51, in the wire structure according to this embodiment, carbon nanotubes 4 and copper wires 52 are formed inside a trench 2. Concretely speaking, as shown in FIG. 52, the trench 2 is divided by partitioning conductive films 50. Thus, this trench 2 has sections (first sections) wherein the carbon nanotubes 4 are formed, and sections (second sections) where the copper wires 52 are formed.

In addition, as shown in FIG. 51, a second barrier film 53 is formed inside the trench 2 in a first section (at least on the sides and the bottom of the trench 2 in a first section) where a copper wire 52 is formed. Here, the second barrier film 53 is a film used for suppressing (preventing) the diffusion of copper from the copper wire 52 into the interlayer insulating film 1. Titanium nitride (TiN) or the like can be adopted as this second barrier film 53.

The other configurations are the same as those in the tenth embodiment; therefore, the descriptions thereof are herein omitted.

As described above, the copper wires 52 are provided partially in the wire structure according to this embodiment. Accordingly, in the case where wires are provided above and beneath the interlayer insulating film 1 so as to sandwich the interlayer insulating film 1, a copper wire 52 can be made to function as a pad for a via. That is, a copper wire 52 is connected to another wire through a via. Here, it is very difficult, in the view of the manufacturing process, for a first section where carbon nanotubes 4 are formed to be made to function as a pad portion for a via.

Here, in the present invention, the term “copper wire” is used for the purpose of convenience in both cases where it functions only as a wire, and where it functions as a wire and a pad (that is, in a case where it functions as a means for conveying electricity).

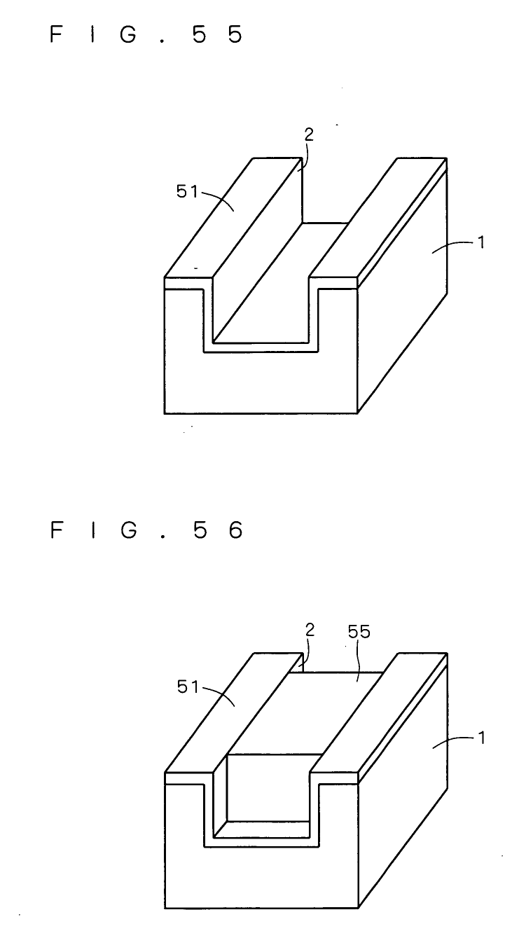

Here, such a via may be formed of carbon nanotubes 4 as shown in FIG. 53. In this case, the second barrier film 53 may be formed so as to include a catalyst that becomes the core of the growth of the carbon nanotubes 4. By doing this, carbon nanotubes 4 can be easily grown between the upper and lower wires. That is, a via made of carbon nanotubes 4 can be formed (Japanese Patent Application Laid-Open Nos. 2004-6864 and 2004-87510).

In addition, a second barrier film 53 is formed in the wire structure according to this embodiment. Accordingly, the diffusion of copper from a copper wire 52 to the interlayer insulating film 1 can be suppressed (prevented).

Here, in this embodiment, as shown in FIG. 54, a first barrier film 51 may be formed inside the trench 2 in the same manner as described in the eleventh embodiment.

### Thirteenth Embodiment

In accordance with a thirteenth embodiment, a manufacturing method of the wire structure according to the eleventh embodiment is described. Here, the wire structure according to the tenth embodiment can be formed in accordance with the method of this embodiment in the case where the step of forming the first barrier film 51 is omitted.

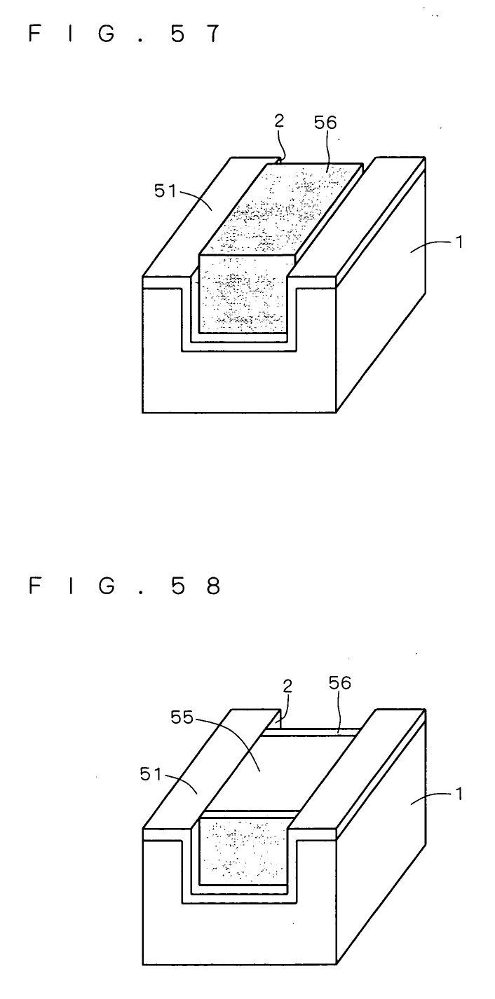

As shown in FIG. 55, an interlayer insulating film 1 is formed on a semiconductor substrate (not shown) which can be used as a base. After that, as shown in FIG. 55, a trench 2 for a wire is formed in the surface of the interlayer insulating film 1. Next, as shown in FIG. 55, a first barrier film 51 is formed on the interlayer insulating film 1 so as to cover the bottom and the sides of this trench 2.

Here, silicon nitride, tantalum nitride, or the like can be adopted as this first barrier film 51. In addition, this first barrier film 51 can be formed in accordance with, for example, a CVD (Chemical Vapor Deposition) method or a sputtering method. In addition, the first barrier film 51 is a film used for suppressing (preventing) the diffusion of a catalyst into the interlayer insulating film 1 as described above.

Next, a plurality of partitioning conductive films 50 are formed of catalyst films so as to partition this trench 2 along the direction in which the trench 2 extends. A method for the formation of this is described below in detail.

First, as shown in FIG. 56, a base block 55 having a substantially rectangular parallelepiped shape is formed in a predetermined region in the trench 2. Here, this base block 55 is a member that becomes the foundation for the formation of partitioning conductive films 50. Conductors such as aluminum, copper, gold, and polysilicon, as well as insulators such as a silicon oxide film, for example, can be adopted as the base block 55. Here, in this embodiment, polysilicon is adopted as the base block 55.

Here, only one base block 55 is formed in FIG. 56. However, base blocks such as the base block 55 can naturally be formed at predetermined intervals in the trench 2.

In addition, concretely speaking, this base block 55 can be formed in the following process.

First, a film of polysilicon or the like is formed on the interlayer insulating film 1 so as to cover the trench 2. After that, the portions of the polysilicon other than those in the trench 2 are removed by means of CMP (Chemical and Mechanical Polishing). Next, a process using photolithographic technology and an etching process is carried out. As a result of this, the polysilicon inside the trench 2 is selectively removed. Thus, base blocks including the base block 55 remain at predetermined intervals, for example, inside this trench 2.

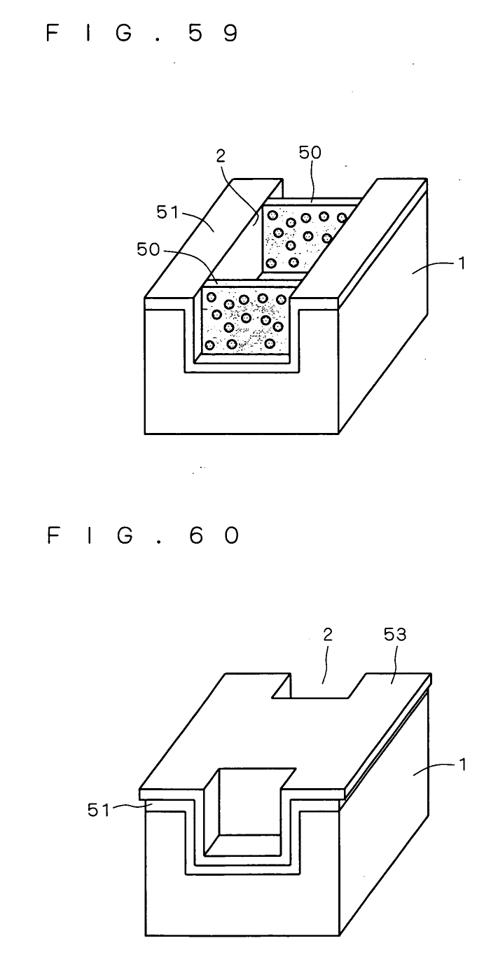

Here, after the completion of the formation of this base block 55, as shown in FIG. 57, a conductive film (hereinafter referred to as catalyst film) 56 is formed of a catalyst of carbon nanotubes 4 on exposed surfaces (upper surface and sides) of this base block 55. The formation of this catalyst film 56 can be carried out in accordance with, for example, a CVD method, a sputtering method, and a plating method.

In addition, cobalt, iron, nickel, tungsten, or a compound that includes these can be adopted as this catalyst film 56. In the case where cobalt or the like is adopted as the catalyst film 56, the following method for forming the catalyst film 56 can be adopted in this embodiment (that is, the base block 55 is made of polysilicon).

A sputtering process is carried out on the base block 55 made of polysilicon. As a result of this, cobalt, iron, nickel, or the like is formed on the base block 55. After that, heat treatment is carried out on this base block 55. At this time, the metal on the polysilicon reacts with the silicon so as to form a silicide. Accordingly, the metal (silicide) can be easily left on the polysilicon by means of a wet process. As a result of this, the catalyst film 56, which is a silicide film, can be formed on the base block 55.

In addition, a method for selectively depositing a metal on a silicon surface by means of plating, for example, is described in a document (Conference of Seven Chemistry Related Societies in Tohoku Region, “Electrolytic Deposition of Metal on Porous Silicon” by Norio Yasui et. al., October 2002). Here, silicon is once converted to porous silicon having microscopic pores. Then, a metal such as Cu, Co, Cr, Mn, Fe, Ni, Zn, Ag, Cd, Tl, Pb, or the like is attached to the silicon. Such polysilicon to which a metal is attached may be adopted as it is in this embodiment.

Next, the portion of the catalyst film 56 which is formed on the upper surface of this base block 55 is removed in order to expose the upper surface of the base block 55. FIG. 58 shows a state after this portion of the catalyst film 56 has been removed. Here, the selective removal of this catalyst film 56 becomes possible by carrying out a CMP process on the portion of the catalyst film 56 that is formed on the upper surface of this base block 55. In addition, the selective removal of this catalyst film 56 becomes possible by carrying out an anisotropic dry etching process.

Here, as can be seen from FIG. 58, the portions of the catalyst film 56 which are formed on the sides of the base block 55 remain.

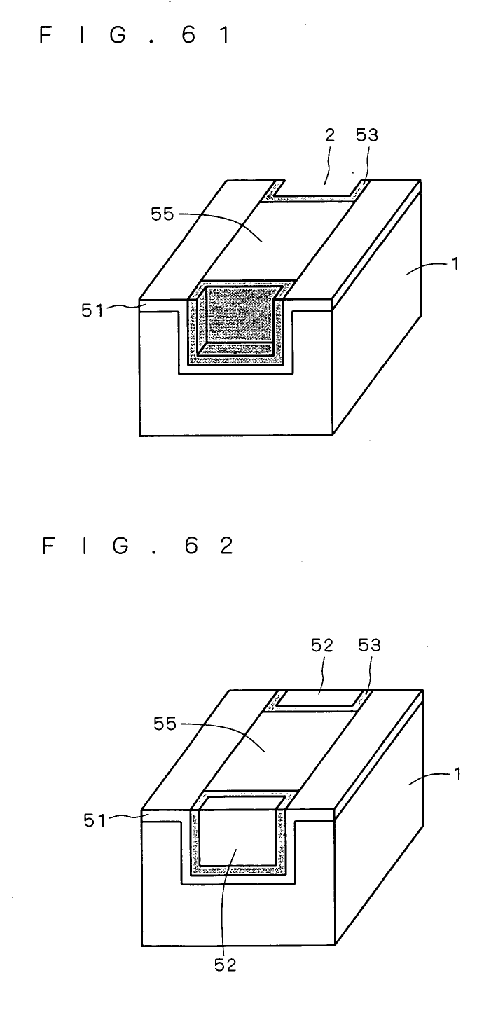

Next, the base block 55 is removed from the exposed portion (upper surface portion). As a result of this, as shown in FIG. 59, partitioning conductive films 50 can be formed within the trench 2. Here, the removal of this base block 55 can be carried out, for example, by utilizing a difference in the etching rate.

As well known, there is a great difference in the etching rate between polysilicon and a silicide, such as a cobalt silicide. Accordingly, an etching process is carried out on the aforementioned base block 55 under predetermined conditions. As a result of this, only partitioning conductive films 50, which are catalyst films 53, can be left within the trench 2.

Here, it can be seen from the above description that an arbitrary material can be selected for the base block 55 as long as it can be etched more easily than the catalyst films 56 under predetermined etching conditions.

Here, in the case where a material that does not include a catalyst as a component, is adopted as the conductive film 56 in the step shown in FIG. 57, a catalyst may be selectively formed on the sides of these conductive films 56 after the selective removal of this base block 55.

As a result of this, the configuration shown in FIG. 59 can be obtained in the same manner as described above. In the case where a catalyst is formed also on the upper surface portions of the conductive films 56, a CMP process or anisotropic dry etching may be carried out on these conductive films 56. As a result of this, the catalyst can be selectively formed only on the sides of the conductive films 56.

In addition, additional catalysts may be formed on the partitioning conductive films 50 shown in FIG. 59 (that is, on the catalyst films 56 which have been adopted as the conductive films 56 as described above). As a result of this, effects such as an increase in the number of the carbon nanotubes 4 to be grown can be attained.

Finally, carbon nanotubes 4 are grown so as to connect the partitioning conductive films 50. At this time, the carbon nanotubes 4 grow on the base of the catalyst. Alternatively, the carbon nanotubes 4 grow in a state where the catalyst is attached to the tip ends of the carbon nanotubes. Here, if the carbon nanotubes 4 are grown in a state where an electrical field is applied, the direction in which these carbon nanotubes 4 grow can be controlled in a predetermined direction (direction of this electrical field) (for example, Japanese Patent Application Laid-Open No. 2002-329723).

The manufacturing method according to this embodiment is adopted as described above, so that the wire structure (FIG. 50) according to the eleventh embodiment can be fabricated. Here, as described above, in the case where the step of forming the first barrier film 51 is omitted, the wire structure (FIG. 49) according to the tenth embodiment can be formed.

In addition, the following method is adopted at the time of the formation of the partitioning conductive films 50 in this embodiment. That is, the base block 55 is formed inside the trench 2 and the catalyst film 56 of the carbon nanotubes is formed on the surfaces of this base block 55. After that, the upper surface of the base block 55 is exposed and the base block 55 is selectively removed from this exposed portion. As a result of these sequential steps, the partitioning conductive films 50 are formed inside the trench 2.

Accordingly, the partitioning conductive films 50 which are spaced at predetermined intervals can be easily fabricated inside the trench 2.

In addition, the base block 55 is etched more easily than the catalyst films 56 under predetermined etching conditions. Accordingly, the base block 55 is etched under these predetermined conditions, so that the base block 55 can be removed from the aforementioned exposed portion. That is, only the catalyst films 56 that become partitioning conductive films 50 can be left in the trench 2.

In addition, in this embodiment, the step of forming a first barrier film 51 inside the trench 2 is additionally provided before the formation of the partitioning conductive films 50. Accordingly, the diffusion of the catalyst from the partitioning conductive films 50 into the interlayer insulating film 1 can be suppressed or prevented due to the function of this first barrier film 51.

Here, a material made of a catalyst of carbon nanotubes 4 may be adopted as the base block 55. Thus, a predetermined portion of the base block 55 is selectively removed, so that partitioning conductive films 50 are formed inside the trench 2.

By doing this, the formation of the catalyst film 56 on the base block 55, and the selective removal process of the catalyst film 56 from the upper surface of the base block 55, which are described above, can be omitted.

### Fourteenth Embodiment

In a fourteenth embodiment, a manufacturing method of the wire structure according to the twelfth embodiment is described.

First, a structure as shown in FIG. 56 is prepared in accordance with a method as described in the thirteenth embodiment. Here, as described above, a first barrier film 51 such as silicon nitride is formed in order to suppress (prevent) the diffusion of a catalyst into the interlayer insulating film 1. In addition, silicon oxide, polysilicon, or the like may be adopted as a base block 55.

Next, in a trench 2, carbon nanotubes 4 are grown in first sections which is divided by partitioning conductive films 50 and a copper wire 52 is formed in second sections which is divided by partitioning conductive films 50 (FIG. 52). Concretely speaking, the structure is as follows. The region where the base block 55 is formed in FIG. 56 becomes first sections. In addition, the regions where the base block 55 is not formed become second sections.

Before the formation of the copper wires 52, second barrier films 53 are formed inside the trenches 2 in the aforementioned second sections. Here, the second barrier films 53 are films used for suppressing (preventing) the diffusion of copper into the interlayer insulating film 1. TiN, Ta, TaN, or the like can be adopted as the second barrier films 53.

In order to form the second barrier films 53 in the aforementioned second sections, initially, a second barrier film 53 is formed on the interlayer insulating film 1 so as to cover the trenches 2 and the base block 55 of a structure as shown in FIG. 56 (FIG. 60).

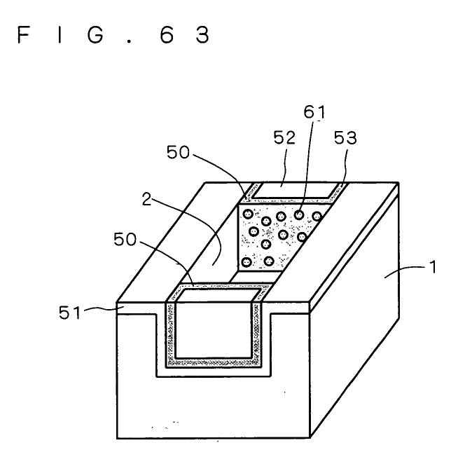

Next, this second barrier film 53 is selectively removed so that the second barrier films 53 remain only on the bottoms and the sides within the trenches 2 in the second sections. FIG. 61 shows a state after the selective removal of this second barrier film 53. Here, as a result of the selective removal of this second barrier film 53, as shown in FIG. 61, the upper surface of the base block 55 is exposed.

Here, a CMP process that is carried out on the upper surface of a structure as shown in FIG. 60 can be cited as a method for selectively removing this second barrier film 53. In addition to this, an anisotropic dry etching process that is carried out on the second barrier film 53 can be adopted. Here, in the case where such an anisotropic dry etching process is adopted, it is necessary to form an etching stopper film (not shown) such as an organic material on the bottoms of the trenches 2 in the second sections before this anisotropic dry etching is carried out. Otherwise, the portions of the second barrier film 53 on the bottoms of the trenches 2 in the second sections will also be removed.

Next, as shown in FIG. 62, the trenches 2 in the second sections are filled in with copper. That is, copper wires 52 are formed in these second sections. Here, a copper plating method, for example, can be adopted as a method for forming these copper wires 52. Here, the copper wires 52 function as a wire or function as a wire and a pad (that is, a carrier of electricity) depending on the place where they are formed.

Next, in FIG. 62, the base block 55, of which the upper surface is exposed, is removed by means of an etching process or the like. As a result of this, as shown in FIG. 63, partitioning conductive films 50 are formed of the second barrier films 53. As described above, a plurality of partitioning conductive films 50 are formed so as to partition the trench 2 along the direction in which the trench 2 extends.

Next, as shown in FIG. 63, a metal catalyst 61 that becomes the core of the growth of carbon nanotubes is selectively formed on the sides of the partitioning conductive films 50. The formation of the catalyst 61 can be carried out in accordance with, for example, a CVD method, a sputtering method, and a plating method. Concretely speaking, as described with reference to FIGS. 56 and 57, a method for selectively leaving a metal (silicide) on the silicon by converting the sputtered metal into the silicide or a method using electrolytic plating can be used.

If a metal catalyst 61 is formed also on the upper surfaces of the partitioning conductive films 50, the portions of the metal catalyst 61 on these upper surfaces can be removed by means of a CMP process, anisotropic dry etching, or the like.

In addition, it is assumed that a film that includes a metal catalyst of carbon nanotubes 4 such as cobalt, iron, or nickel is adopted as the second barrier film 53 at the stage of the formation of the second barrier film 53. In such a case, the aforementioned step of selectively forming the metal catalyst 61 can be omitted.

Finally, carbon nanotubes 4 are grown so as to connect the partitioning conductive films 50 in the first sections. At this time, the carbon nanotubes 4 are grown on the base of the catalyst. Alternatively, the carbon nanotubes 4 grow in a state where the catalyst is attached to the tip ends of the carbon nanotubes. Here, if carbon nanotubes 4 are grown in a state where an electrical field is applied, the direction in which these carbon nanotubes 4 grow can be controlled in a predetermined direction (direction of this electrical field).

As described above, the manufacturing method according to this embodiment is adopted, so that the wire structure (FIG. 51) according to the twelfth embodiment, which is provided with first sections where carbon nanotubes 4 are formed and second sections where a copper wire 52 is formed, can be fabricated.

In this embodiment, the step of forming second barrier films 53 inside the trenches 2 in the second sections is further provided before the formation of copper wires 52. Accordingly, the diffusion of copper from a copper wire 52 to the interlayer insulating film 1 can be suppressed or prevented by the function of these second barrier films 53.

Each of the aforementioned wire structures can be applied to a general semiconductor product where the wire width is 50 nm or less, so that the desired effects thereof can be attained. In addition, in the case where a current of which the current density exceeds 10⁵ A/cm² flows through a wire for a long time, the desired effects thereof can be attained.

While the invention has been shown and described in detail, the foregoing description is in all aspects illustrative and not restrictive. It is therefore understood that numerous modifications and variations can be devised without departing from the scope of the invention.

What is claimed is:

1. A wire structure for a semiconductor device, wherein
said semiconductor device comprises an insulating film formed on a base, and said wire structure comprises:
a trench formed in a surface of said insulating film; and
a plurality of carbon nanotubes that exist in said trench.

2. The wire structure according to claim 1, wherein
said carbon nanotubes are formed in a direction, including a direction component in which said trench extends.

3. The wire structure according to claim 2, wherein
each of said carbon nanotubes is formed in the same direction.

4. The wire structure according to claim 1, wherein
said trench has a cross section of a substantially rectangular shape, and
the wire structure further comprises a catalyst film for said carbon nanotubes, which is formed in a direction in which said trench extends, on at least one inner surface of said trench.

5. The wire structure according to claim 4, wherein
said catalyst film is formed on one inner surface of said trench, and
said carbon nanotubes are formed in U shape on said catalyst film.

6. The wire structure according to claim 4, wherein
said catalyst film is formed on the inner surface on the both sides of said trench.

7. The wire structure according to claim 4, wherein
said catalyst film is formed on the inner surface on the both sides and another surface of said trench.

8. The wire structure according to claim 7, further comprising:
a growth suppressing film for suppressing growth of said carbon nanotubes on said catalyst film, which is formed on a portion of said catalyst film which exists on a bottom of said trench.

9. The wire structure according to claim 6, wherein
said carbon nanotubes are formed from a portion of said catalyst film that is formed on one inner surface of said trench, to a portion of said catalyst film that is formed on another surface.

10. The wire structure according to claim 4, wherein
said catalyst film has conductivity.

11. The wire structure according to claim 7, wherein
said catalyst film is made of a magnetic material.

12. The wire structure according to claim 1, further comprising:
a conductor that fills in said trench.

13. The wire structure according to claim 12, wherein
said conductor is made of copper.

14. The wire structure according to claim 12, further comprising:
a barrier film for suppressing the diffusion of said conductor in said insulating film, which is formed inside said trench.

15. A semiconductor device comprising the wire structure according to claim 1.

16. An MRAM comprising:
a first wire that is provided above a semiconductor substrate;
a second wire that exists above said semiconductor substrate and below said first wire, and crosses said first wire in a plan view; and
an MTJ film that exists between said first wire and said second wire, wherein
at least one of said first wire and said second wire comprises the wire structure according to claim 11, and comprises no catalyst film on a surface that faces said MTJ film.

17. A manufacturing method of a semiconductor device, comprising the steps of:
(a) forming an insulating film on a base;
(b) forming a trench for a wire in a surface of said insulating film;
(c) forming a catalyst film inside said trench; and
(d) growing carbon nanotubes on said catalyst film.

18. The manufacturing method of a semiconductor device according to claim 17, wherein
in said step (d), an electrical field comprising a direction component in which said trench extends is applied while said carbon nanotubes are grown on said catalyst film.

19. A manufacturing method of a semiconductor device, comprising the steps of:
(A) forming an insulating film on a base;
(B) forming a trench for a wire inside a surface of said insulating film;
(C) forming a plurality of catalyst films in island form on at least one inner surface of said trench in a direction in which said trench extends; and
(D) growing carbon nanotubes in a state where said catalyst films in island form are attached to tip ends of said carbon nanotubes which do not make contact with an inner surface of said trench.

20. The manufacturing method of a semiconductor device according to claim 19, wherein
said step (D) includes the step of growing said carbon nanotubes using a plasma CVD method.

21. The manufacturing method of a semiconductor device according to claim 19, wherein
in said step (B), said trench having a cross section of a rectangular shape is formed in the surface of said insulating film;
in said step (C), said pluarlity of catalyst films in island form are formed on a bottom of said trench;
in said step (D), said carbon nanotubes are grown upward from the bottom of said trench; and
the manufacturing method of a semiconductor device further comprises the step of (E) removing said catalyst films that are attached to the tip ends of said carbon nanotubes.

22. The wire structure according to claim 2, further comprising
a plurality of partitioning conductive films which are formed inside said trench and partition said trench along a direction in which said trench extends, wherein
said carbon nanotubes are formed so as to connect said partitioning conductive films.

23. The wire structure according to claim 22, wherein
said partitioning conductive films are catalyst films for said carbon nanotubes.

24. The wire structure according to claim 22, wherein
said partitioning conductive films are formed at equal intervals inside said trench.

25. The wire structure according to claim 23, wherein
a first barrier film for suppressing diffusion of said catalyst from said partitioning conductive film to said insulating film is formed inside said trench.

26. The wire structure according to claim 22, further comprising:
a copper wire that is formed in said trench, wherein
said trench has a section where said carbon nanotubes are formed and a section where said copper wire is formed.

27. The wire structure according to claim 26, wherein
said copper wire is connected to another wire through a via.

28. The wire structure according to claim 27, wherein
said via is formed of carbon nanotubes.

29. The wire structure according to claim 26, wherein
a second barrier film for suppressing diffusion of copper from said copper wire to said insulating film is formed inside said trench, in the section where said copper wire is formed.

30. A semiconductor device comprising the wire structure according to claim 22.

31. A manufacturing method of a semiconductor device, comprising the steps of:
(a) forming an insulating film on a base;
(b) forming a trench for a wire in a surface of said insulating film;
(c) forming a plurality of partitioning conductive films which are made of catalyst films and partition said trench along a direction in which said trench extends; and
(d) growing carbon nanotubes so as to connect said partitioning conductive films.

32. The manufacturing method of a semiconductor device according to claim 31, wherein
said step (c) comprises the steps of:
(c-1) forming a base block in a predetermined region inside said trench;
(c-2) forming a catalyst film for said carbon nanotubes on a surface of said base block;
(c-3) exposing said base block by removing a portion of said catalyst film that has been formed on an upper surface of said base block; and
(c-4) forming said partitioning conductive films inside said trench by removing said base block from the exposed portion.

33. The manufacturing method of a semiconductor device according to claim 32, wherein
said base block can be etched more easily than said catalyst film under predetermined conditions, and
in said step (c-4), said base block is etched under said predetermined conditions.

34. The manufacturing method of a semiconductor device according to claim 31, wherein
said step (c) comprises the steps of:
(c-1) forming a base block made of a catalyst for carbon nanotubes in a predetermined region inside said trench; and
(c-2) forming said partitioning conductive films inside said trench by removing a predetermined portion of said base block.

35. The manufacturing method of a semiconductor device according to claim 32, further comprising the step of:
(e) forming, inside said trench, a first barrier film for suppressing diffusion of a catalyst from said partitioning conductive films to said insulating film before said step (c).

36. The manufacturing method of a semiconductor device according to claim 31, wherein
in said step (d), said carbon nanotubes are grown in a first section which is partitioned by said partitioning conductive films, and a copper wire is formed in a second section which is partitioned by said partitioning conductive films.

37. The manufacturing method of a semiconductor device according to claim 36, further comprising the step of:
(f) forming, inside said trench in said second section, a second barrier film for suppressing diffusion of copper into said insulating film, before the formation of said copper wire.
